(19) United States
(12) Patent Application Publication
(10) Pub. No.: US 2024/0215359 A1
(43) Pub. Date: Jun. 27, 2024

(54) DISPLAY DEVICE, ELECTRONIC DEVICE, AND METHOD FOR MANUFACTURING DISPLAY DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Shuichi KATSUI, Atsugi, Kanagawa (JP); Hidetomo KOBAYASHI, Isehara, Kanagawa (JP)

(21) Appl. No.: 18/554,148

(22) PCT Filed: Mar. 20, 2022
(86) PCT No.: PCT/IB2022/052919

§ 371 Date: Oct. 5, 2023

(30) Foreign Application Priority Data
Apr. 8, 2021 (JP) 2021-065826

(51) Int. Cl. H10K 59/131; H10K 59/12; H10K 59/121; H10K 59/35; H10K 71/00

(52) U.S. Cl. CPC H10K 59/131; H10K 59/1201; H10K 59/1213; H10K 59/352; H10K 59/353; H10K 71/00

(57) ABSTRACT

A display device with high display quality is provided. A highly reliable display device is provided. A display device with low power consumption is provided. A display device that can easily achieve higher definition is provided. A display device with both high display quality and high definition is provided. A display device with high contrast is provided. The display device includes a first wiring to a fourth wiring and a display portion including a first pixel to a third pixel. The second pixel is positioned between the first pixel and the third pixel in a plan view. Each pixel includes a first subpixel and a second subpixel. The first wiring has a function of applying a first potential to the second subpixel included in the first pixel. The second wiring has a function of applying the first potential to the first subpixel included in the second pixel. The third wiring has a function of applying the first potential to the second subpixel included in the second pixel. The fourth wiring has a function of applying the first potential to the first subpixel included in the third pixel. The first wiring and the second wiring are adjacent to each other. The third wiring and the fourth wiring are adjacent to each other. A distance between the first wiring and the second wiring is shorter than a distance between the third wiring and the fourth wiring.

### TECHNICAL FIELD

One embodiment of the present invention relates to a display device. Another embodiment of the present invention relates to a method for manufacturing a display device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-definition display panels have been required. Examples of devices that require high-definition display panels include a smartphone, a tablet terminal, a laptop computer, and the like. In addition, higher definition has been required for a stationary display device such as a television device or a monitor device with an increase in resolution. Furthermore, a device for virtual reality (VR) or augmented reality (AR) is given as an example of a device that is required to have the highest definition.

In addition, examples of a display device that can be employed for a display panel include, typically, a liquid crystal display device, a light-emitting apparatus including a light-emitting element such as an organic EL (Electro Luminescence) element or a light-emitting diode (LED), electronic paper performing display by an electrophoretic method or the like, and the like.

For example, the basic structure of an organic EL element is a structure in which a layer containing a light-emitting organic compound is sandwiched between a pair of electrodes. By applying voltage to this element, light emission can be obtained from the light-emitting organic compound. A display device employing such an organic EL element does not need a backlight that is necessary for a liquid crystal display device and the like; thus, a thin, lightweight, high-contrast, and low-power display device can be achieved. Patent Document 1, for example, discloses an example of a display device using an organic EL element.

Patent Document 2 discloses a display device using an organic EL device for VR.

### REFERENCE

### Patent Document

[Patent Document 1] Japanese Published Patent Application No. 2002-324673
[Patent Document 2] PCT International Publication No. 2018/087625

### SUMMARY OF THE INVENTION

### Problems to be Solved by the Invention

An object of one embodiment of the present invention is to provide a display device with high display quality. An object of one embodiment of the present invention is to provide a highly reliable display device. An object of one embodiment of the present invention is to provide a display device with low power consumption. An object of one embodiment of the present invention is to provide a display device that can easily achieve higher definition. An object of one embodiment of the present invention is to provide a display device with both high display quality and high definition. An object of one embodiment of the present invention is to provide a display device with high contrast.

An object of one embodiment of the present invention is to provide a display device having a novel structure or a method for manufacturing a display device. An object of one embodiment of the present invention is to provide a method for manufacturing the above display device with high yield. An object of one embodiment of the present invention is to at least reduce at least one of problems of prior art.

Note that the description of these objects does not preclude the presence of other objects. Note that in one embodiment of the present invention, there is no need to achieve all the objects. Note that other objects can be derived from the description of the specification, the drawings, the claims, and the like.

### Means for Solving the Problems

One embodiment of the present invention is a display device that includes a display portion, a first wiring, a second wiring, a third wiring, and a fourth wiring. The display portion includes a first pixel, a second pixel, and a third pixel. The second pixel is positioned between the first pixel and the third pixel in a plan view. The first pixel, the second pixel, and the third pixel each include a first subpixel and a second subpixel. The first wiring has a function of applying a first potential to the second subpixel included in the first pixel. The second wiring has a function of applying the first potential to the first subpixel included in the second pixel. The third wiring has a function of applying the first potential to the second subpixel included in the second pixel. The fourth wiring has a function of applying the first potential to the first subpixel included in the third pixel. The first wiring and the second wiring are adjacent to each other. The third wiring and the fourth wiring are adjacent to each other. A distance between the first wiring and the second wiring is shorter than a distance between the third wiring and the fourth wiring.

In addition, in the above structure, it is preferable that the first subpixel have a function of controlling light corresponding to a first color selected from red, green, and blue and that the second subpixel have a function of controlling light corresponding to a second color that is different from the first color among red, green, and blue.

In addition, in the above structure, the display device preferably includes a fifth wiring, a sixth wiring, a seventh wiring, and an eighth wiring. The fifth wiring preferably has a function of supplying a signal to the second subpixel included in the first pixel. The sixth wiring preferably has a function of supplying a signal to the first subpixel included in the second pixel. The seventh wiring preferably has a function of supplying a signal to the second subpixel included in the second pixel. The eighth wiring preferably has a function of supplying a signal to the first subpixel included in the third pixel. The first wiring and the second wiring are preferably placed between the fifth wiring and the sixth wiring in a plan view. The third wiring and the fourth wiring are preferably placed between the seventh wiring and the eighth wiring in a plan view.

In addition, in the above structure, the first pixel, the second pixel, and the third pixel are preferably sequentially arranged along the direction of a first axis. The first wiring to the eighth wiring each preferably include a region extending along the direction of a second axis. The first axis and the second axis are preferably orthogonal to each other.

In addition, in the above structure, the display device preferably includes a display portion driver circuit, a ninth wiring electrically connected to the display portion driver circuit, and a tenth wiring electrically connected to the display portion driver circuit. The ninth wiring and the tenth wiring each preferably have a function of a scan line. The ninth wiring preferably includes a first region overlapped with the first pixel. The tenth wiring preferably includes a second region overlapped with the second pixel and a third region overlapped with the third pixel.

In addition, in the above structure, the second subpixel included in the first pixel preferably includes a first transistor. The first subpixel included in the second pixel preferably includes a second transistor. The second subpixel included in the second pixel preferably includes a third transistor. The first subpixel included in the third pixel preferably includes a fourth transistor. One of a source and a drain of the first transistor is preferably electrically connected to the first wiring. One of a source and a drain of the second transistor is preferably electrically connected to the second wiring. One of a source and a drain of the third transistor is preferably electrically connected to the third wiring. One of a source and a drain of the fourth transistor is preferably electrically connected to the fourth wiring. The first wiring and the second wiring are preferably placed between a channel formation region of the first transistor and a channel formation region of the second transistor. The third wiring and the fourth wiring are preferably placed between the channel formation region of the second transistor and a channel formation region of the third transistor in a plan view.

In addition, in the above structure, the display portion preferably includes a first light-emitting element, a second light-emitting element, a third light-emitting element, and a fourth light-emitting element. The other of the source and the drain of the first transistor is preferably electrically connected to the first light-emitting element. The other of the source and the drain of the second transistor is preferably electrically connected to the second light-emitting element. The other of the source and the drain of the third transistor is preferably electrically connected to the third light-emitting element. The other of the source and the drain of the fourth transistor is preferably electrically connected to the fourth light-emitting element.

In addition, in the above structure, a display portion driver circuit, a ninth wiring electrically connected to the display portion driver circuit, and a tenth wiring electrically connected to the display portion driver circuit are preferably included. The ninth wiring and the tenth wiring each preferably have a function of a scan line. The ninth wiring is preferably electrically connected to a gate of the first transistor. The tenth wiring is preferably electrically connected to a gate of the second transistor, a gate of the third transistor, and a gate of the fourth transistor. A first scan line preferably includes a first region overlapped with the first pixel. A second scan line preferably includes a second region overlapped with the second pixel and a third region overlapped with the third pixel.

In addition, in the above structure, the ninth wiring is preferably overlapped with neither the second pixel nor the third pixel. The tenth wiring is preferably not overlapped with the first pixel. The ninth wiring and the tenth wiring are preferably not in contact with each other in the display portion.

In addition, in the above structure, the display portion driver circuit preferably includes a first scan line driver circuit electrically connected to the ninth wiring and a second scan line driver circuit electrically connected to the tenth wiring. The first scan line driver circuit and the second scan line driver circuit are preferably provided with the display portion therebetween.

Another embodiment of the present invention is a display device that includes a first pixel, a second pixel, a third pixel, a first wiring, a second wiring, and a third wiring. The second pixel is positioned between the first pixel and the third pixel in a plan view. The first pixel, the second pixel, and the third pixel each include a first subpixel, a second subpixel, and a third subpixel. The first subpixel has a function of controlling light corresponding to a first color selected from red, green, and blue. The second subpixel has a function of controlling light corresponding to a second color that is different from the first color among red, green, and blue. The third subpixel has a function of controlling light corresponding to a third color that is different from the first color and the second color among red, green, and blue. The first wiring has a function of applying a first potential to the third subpixel included in the first pixel and the first subpixel included in the second pixel. The second wiring has a function of applying the first potential to the third subpixel included in the second pixel. The third wiring has a function of applying the first potential to the first subpixel included in the third pixel. The second wiring and the third wiring are adjacent to each other. The first wiring has a larger width than one or more of the second wiring and the third wiring.

In addition, in the above structure, the display device preferably includes a fourth wiring, a fifth wiring, a sixth wiring, and a seventh wiring. The fourth wiring preferably has a function of supplying a signal to the second subpixel included in the first pixel. The fifth wiring preferably has a function of supplying a signal to the first subpixel included in the second pixel. The sixth wiring preferably has a function of supplying a signal to the second subpixel included in the second pixel. The seventh wiring preferably has a function of supplying a signal to the first subpixel included in the third pixel. The first wiring is preferably placed between the fourth wiring and the fifth wiring in a plan view. The second wiring and the third wiring are preferably placed between the sixth wiring and the seventh wiring in a plan view.

In addition, in the above structure, the second subpixel included in the first pixel preferably includes a first transistor. The first subpixel included in the second pixel preferably includes a second transistor. The second subpixel included in the second pixel preferably includes a third transistor. The third pixel preferably includes a fourth transistor. One of a source and a drain of the first transistor and one of a source and a drain of the second transistor are preferably electrically connected to the first wiring. One of a source and a drain of the third transistor is preferably electrically connected to the second wiring. One of a source and a drain of the fourth transistor is preferably electrically connected to the third wiring. The first wiring is preferably placed between a channel formation region of the first transistor and a channel formation region of the second transistor. The second wiring and the third wiring are preferably placed between the channel formation region of the second transistor and a channel formation region of the third transistor.

Another embodiment of the present invention is a method for manufacturing a display device that includes a display portion over a first substrate. The method for manufacturing a display device includes a first step of forming n transistors (n is an integer greater than or equal to 2) arranged in a matrix in a region to be the display portion over the first substrate; a second step of depositing a first conductive film over the n transistors; a third step of depositing a photo resist over the first conductive film; a fourth step of transferring a desired pattern through light exposure treatment on the photo resist onto the region to be the display portion; a fifth step of forming the desired pattern on the photo resist through development treatment on the photo resist; a sixth step of forming n wirings by removing part of the first conductive film with the use of the desired pattern; and a seventh step of forming n light-emitting elements arranged in a matrix over the n transistors. The n wirings are electrically connected to the n transistors one by one. The fourth step includes a step of performing light exposure on a plurality of divided light exposure regions over the region to be the display portion. Among the n wirings, a first wiring is formed through light exposure in a first light exposure region, and a second wiring is formed through light exposure in a second light exposure region. The first wiring and the second wiring are adjacent to each other. Among the n transistors, a first transistor is electrically connected to the first wiring, and a second transistor is electrically connected to the second wiring. The first wiring and the second wiring are placed between a channel formation region of the first transistor and a channel formation region of the second transistor in a plan view.

In addition, in the above structure, the n wirings are preferably electrically connected to ones of sources and drains of the n transistors one by one. The others of the sources and the drains of the n transistors are preferably electrically connected to the n light-emitting elements one by one and are overlapped with each other one by one.

In addition, in the above structure, the n light-emitting elements each preferably include an EL layer.

In addition, in the above structure, it is preferable to perform light exposure treatment so that in a connection portion of adjacent light exposure regions in the plurality of light exposure regions, a light exposure region where parts of the adjacent light exposure regions are overlapped with each other is formed.

### Effect of the Invention

According to one embodiment of the present invention, a display device with high display quality can be provided. Alternatively, a highly reliable display device can be provided. Alternatively, a display device with low power consumption can be provided. Alternatively, a display device that can easily achieve higher definition can be provided. Alternatively, a display device with both high display quality and high definition can be provided. Alternatively, a display device with high contrast can be provided.

Alternatively, according to one embodiment of the present invention, a display device having a novel structure or a method for manufacturing a display device can be provided. Alternatively, a method for manufacturing the above display device with high yield can be provided. According to one embodiment of the present invention, at least one of problems of prior art can be at least reduced.

Note that the description of these effects does not preclude the presence of other effects. Note that one embodiment of the present invention does not necessarily have all of these effects. Note that other effects can be derived from the description of the specification, the drawings, and the claims.

### BRIEF DESCRIPTION OF THE DRAWINGS

FIG. 1A and FIG. 1B are perspective views illustrating a structure example of a display device.

FIG. 2A and FIG. 2B are perspective views illustrating a structure example of the display device.

FIG. 3A and FIG. 3B are block diagrams each illustrating a display portion.

FIG. 4A and FIG. 4B are block diagrams each illustrating a display portion.

FIG. 5A to FIG. 5K are diagrams each illustrating a pixel structure example.

FIG. 6A and FIG. 6B are circuit diagrams each illustrating a pixel structure example.

FIG. 7A and FIG. 7B are circuit diagrams each illustrating a pixel structure example.

FIG. 8A and FIG. 8B are diagrams each illustrating a structure example of a display portion.

FIG. 9A to FIG. 9C are diagrams illustrating structure examples of the display portion.

FIG. 10A and FIG. 10B are diagrams each illustrating a structure example of the display portion.

FIG. 11A and FIG. 11B are diagrams each illustrating a pixel structure example.

FIG. 12 is a diagram illustrating a pixel structure example.

FIG. 13 is a circuit diagram illustrating a structure example of a display device.

FIG. 14A and FIG. 14B are diagrams illustrating a structure example of the display portion.

FIG. 15 is a diagram illustrating a structure example of the display portion.

FIG. 16A and FIG. 16B are diagrams illustrating a structure example of the display portion.

FIG. 17 is a diagram illustrating a structure example of the display portion.

FIG. 18A and FIG. 18B are diagrams each illustrating a structure example of the display portion.

FIG. 19A and FIG. 19B are diagrams illustrating a structure example of the display portion.

FIG. 20 is a diagram illustrating a structure example of the display portion.

FIG. 21A and FIG. 21B are diagrams each illustrating a structure example of the display portion.

FIG. 22 is a cross-sectional view illustrating a structure example of a display device.

FIG. 23 is a cross-sectional view illustrating a structure example of a display device.

FIG. 24 is a cross-sectional view illustrating a structure example of a display device.

FIG. 25A and FIG. 25B are cross-sectional views each illustrating a structure example of a display element.

FIG. 26A to FIG. 26F are diagrams each illustrating a structure example of a light-emitting element.

FIG. 27A and FIG. 27B are diagrams illustrating an example of an electronic device.

FIG. 28A to FIG. 28D are diagrams illustrating examples of electronic devices.

FIG. 29A to FIG. 29F are diagrams illustrating examples of electronic devices.

FIG. 30A to FIG. 30F are diagrams illustrating examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same reference numerals are commonly used for the same portions or portions having similar functions in different drawings, and a repeated description thereof is omitted. Moreover, similar functions are denoted by the same hatch pattern and are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number of components.

In addition, in this specification and the like, the term “film” and the term “layer” can be interchanged with each other. For example, in some cases, the term “conductive layer” or “insulating layer” can be interchanged with the term “conductive film” or “insulating film.”

Note that in this specification, an EL layer refers to a layer that contains at least a light-emitting substance (also referred to as a light-emitting layer) or a stack including the light-emitting layer provided between a pair of electrodes of a light-emitting element.

In this specification and the like, a display panel that is one embodiment of a display device has a function of displaying (outputting), for example, an image on (to) a display surface. Therefore, the display panel is one embodiment of an output device.

Furthermore, in this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

A light-emitting element according to one embodiment of the present invention may include layers containing a substance with a high hole-injection property, a substance with a high hole-transport property, a substance with a high electron-transport property, a substance with a high electron-injection property, a substance with a bipolar property, and the like.

Note that the light-emitting layer and the layers containing a substance with a high hole-injection property, a substance with a high hole-transport property, a substance with a high electron-transport property, a substance with a high electron-injection property, a substance with a bipolar property, and the like may each include an inorganic compound such as a quantum dot or a high molecular compound (an oligomer, a dendrimer, a polymer, or the like). For example, a quantum dot used for the light-emitting layer can function as a light-emitting material.

Note that as a quantum dot material, a colloidal quantum dot material, an alloyed quantum dot material, a core-shell quantum dot material, a core quantum dot material, or the like can be used. Alternatively, a material containing elements belonging to Groups 12 and 16, elements belonging to Groups 13 and 15, or elements belonging to Groups 14 and 16 may be used. Alternatively, a quantum dot material containing an element such as cadmium, selenium, zinc, sulfur, phosphorus, indium, tellurium, lead, gallium, arsenic, or aluminum may be used.

In this specification and the like, a device manufactured using a metal mask or an FMM (a fine metal mask or a high-definition metal mask) is sometimes referred to as a device having an MM (a metal mask) structure. In addition, in this specification and the like, a device manufactured without using a metal mask or an FMM is sometimes referred to as a device having an MML (metal maskless) structure.

Note that in this specification and the like, a structure in which light-emitting layers in light-emitting devices of respective colors (here, blue (B), green (G), and red (R)) are separately formed or the light-emitting layers are separately patterned is sometimes referred to as an SBS (Side By Side) structure. In addition, in this specification and the like, a light-emitting device capable of emitting white light is sometimes referred to as a white light-emitting device. Note that a combination of a white light-emitting device with a coloring layer (e.g., a color filter) enables a full-color display device.

In addition, light-emitting devices can be roughly classified into a single structure and a tandem structure. A device having a single structure includes one light-emitting unit between a pair of electrodes, and the light-emitting unit preferably includes one or more light-emitting layers. In the case where two light-emitting layers are used to obtain white light emission, the two light-emitting layers are selected so that emission colors of the two light-emitting layers have a relationship of complementary colors. For example, when an emission color of a first light-emitting layer and an emission color of a second light-emitting layer have a relationship of complementary colors, it is possible to obtain a structure where the light-emitting device can emit white light as a whole. Furthermore, in the case where three or more light-emitting layers are used to obtain white light emission, the light-emitting device is configured to be able to emit white light as a whole by combining the emission colors of the three or more light-emitting layers.

A device having a tandem structure includes a plurality of light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the single structure. Note that in the device having the tandem structure, an intermediate layer such as a charge-generation layer is suitably provided between the plurality of light-emitting units.

Furthermore, when the white light-emitting device (the single structure or the tandem structure) and a light-emitting device having an SBS structure are compared, the light-emitting device having the SBS structure can have lower power consumption than the white light-emitting device. In the case where the power consumption is required to be low, the light-emitting device having the SBS structure is suitably used. Meanwhile, the white light-emitting device is preferable in terms of low manufacturing cost or high manufacturing yield because the manufacturing process of the white light-emitting device is simpler than that of the light-emitting device having the SBS structure.

### Embodiment 1

In this embodiment, structure examples of a display device according to one embodiment of the present invention and an example of a method for manufacturing the display device will be described.

One embodiment of the present invention is a display device including a light-emitting element (also referred to as a light-emitting device). The display device includes at least two light-emitting elements that emit light of different colors. The light-emitting elements each include a pair of electrodes and an EL layer therebetween. As the light-emitting elements, electroluminescent elements such as organic EL elements or inorganic EL elements can be used. Besides, light-emitting diodes (LEDs) can be used. The light-emitting elements according to one embodiment of the present invention are preferably organic EL elements (organic electroluminescent elements). Two or more light-emitting elements that exhibit different colors include EL layers containing different materials. For example, when three kinds of light-emitting elements that emit red (R), green (G), and blue (B) light are included, a full-color display device can be achieved.

Here, in the case where the EL layers are separately formed between light-emitting elements of different colors, an evaporation method using a shadow mask such as a metal mask is known. However, this method causes a deviation from the designed shape and position of an island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve high definition and high aperture ratio. In addition, dust derived from a material attached to the metal mask in evaporation is generated in some cases. Such dust might cause defective patterning of the light-emitting elements. Furthermore, short circuit derived from the dust may occur. Moreover, a step of cleaning the material attached to the metal mask is necessary. Thus, a measure has been taken for pseudo increase in definition (also referred to as pixel density) by employing a unique pixel arrangement such as a PenTile arrangement.

In one embodiment of the present invention, fine patterning of EL layers is performed without a shadow mask such as a metal mask. Accordingly, it is possible to achieve a display device with high definition and high aperture ratio that has been difficult to achieve. Moreover, since the EL layers can be formed separately, it is possible to achieve a display device that performs extremely clear display with high contrast and high display quality.

Here, for easy understanding, a description is made on the case where EL layers are separately formed for light-emitting elements of two colors. First, a stack of a first EL film and a first sacrificial film is formed to cover a pixel electrode. Next, a resist mask is formed over the first sacrificial film. Then, part of the first sacrificial film and part of the first EL film are etched using the resist mask, so that a first EL layer and a first sacrificial layer over the first EL layer are formed.

Next, a stack of a second EL film and a second sacrificial film is formed. Then, part of the second sacrificial film and part of the second EL film are etched using the resist mask, so that a second EL layer and a second sacrificial layer over the second EL layer are formed. Next, the pixel electrode is processed using the first sacrificial layer and the second sacrificial layer as a mask, so that a first pixel electrode overlapped with the first EL layer and a second pixel electrode overlapped with the second EL layer are formed. In this manner, the first EL layer and the second EL layer can be separately formed. Finally, the first sacrificial layer and the second sacrificial layer are removed and a common electrode is formed, so that light-emitting elements of two colors can be separately formed.

Furthermore, by repeating the above, EL layers in light-emitting elements of three or more colors can be separately formed, so that a display device including light-emitting elements of three colors or four or more colors can be achieved.

At an end portion of the EL layer, a step is generated owing to a region where the pixel electrode and the EL layer are provided and a region where the pixel electrode and the EL layer are not provided. At the time of forming the common electrode over the EL layer, coverage with the common electrode is degraded owing to the step at the end portion of the EL layer, which might cause disconnection of the common electrode. Furthermore, the common electrode might become thinner, so that electric resistance might be increased.

In the case where an end portion of the pixel electrode is substantially aligned with the end portion of the EL layer and the case where the end portion of the pixel electrode is positioned outside the end portion of the EL layer, the common electrode and the pixel electrode are sometimes short-circuited when the common electrode is formed over the EL layer.

In one embodiment of the present invention, an insulating layer is provided between the first EL layer and the second EL layer, so that unevenness on a surface where the common electrode is provided can be reduced. Thus, the coverage with the common electrode can be increased at the end portion of the first EL layer and the end portion of the second EL layer, and favorable conductivity of the common electrode can be achieved. In addition, short circuit between the common electrode and the pixel electrode can be inhibited.

In the case where EL layers of different colors are adjacent to each other, it is difficult to set a distance between the EL layers adjacent to each other to be less than 10 μm with a formation method using a metal mask, for example; however, with the above method, the distance can be decreased to be less than or equal to 3 μm, less than or equal to 2 μm, or less than or equal to 1 μm. For example, with the use of a light exposure apparatus for LSI, the distance can be decreased to be less than or equal to 500 nm, less than or equal to 200 nm, less than or equal to 100 nm, or less than or equal to 50 nm. Accordingly, the area of a non-light-emitting region that might exist between two light-emitting elements can be significantly reduced, and the aperture ratio can be close to 100%. For example, an aperture ratio higher than or equal to 50%, higher than or equal to 60%, higher than or equal to 70%, higher than or equal to 80%, or higher than or equal to 90% and lower than 100% can be achieved.

In addition, the pattern of the EL layer itself can be made extremely smaller than that in the case of using a metal mask. Furthermore, for example, in the case of using a metal mask for forming EL layers separately, a variation in the thickness occurs between the center and the edge of the pattern; thus, an effective area that can be used as a light-emitting region with respect to the entire pattern area is reduced. In contrast, in the above manufacturing method, a pattern is formed by processing a film deposited to have uniform thickness, which enables uniform thickness in the pattern; thus, even with a fine pattern, almost the entire area can be used as a light-emitting region. Therefore, the above manufacturing method makes it possible to achieve both high definition and high aperture ratio.

As described above, with the above manufacturing method, a display device in which minute light-emitting elements are integrated can be achieved, and it is not necessary to conduct a pseudo increase in definition by employing unique pixel arrangement such as PenTile arrangement; thus, the display device can achieve a definition higher than or equal to 500 ppi, higher than or equal to 1000 ppi, higher than or equal to 2000 ppi, higher than or equal to 3000 ppi, or higher than or equal to 5000 ppi while having what is called a stripe pattern where R, G, and B are arranged in one direction.

### [Structure Example of Display Device]

Structure examples of a display device according to one embodiment of the present invention will be described below.

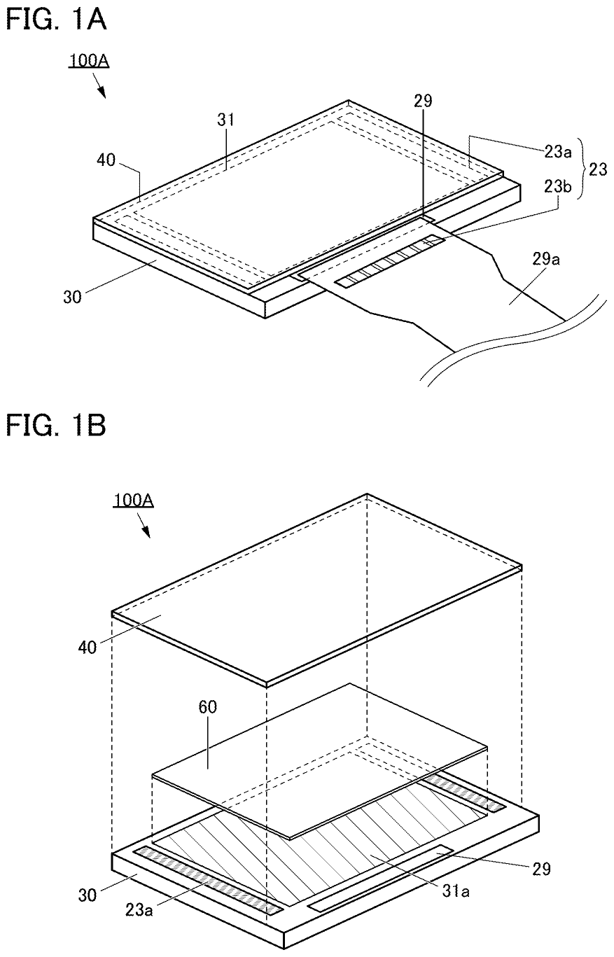

FIG. 1A is a perspective schematic view of a semiconductor device 100A according to one embodiment of the present invention. The semiconductor device 100A includes a layer 30 and a sealing substrate 40 over the layer 30. The semiconductor device 100A includes a display portion 31, and the display portion 31 includes a region 31a provided in the layer 30 and a layer 60. The region 31a includes a plurality of pixel circuits arranged in a matrix. The layer 30 has the region 31a, and the layer 60 is provided between the sealing substrate 40 and the region 31a. For easy understanding of the structure of the semiconductor device 100A illustrated in FIG. 1A, FIG. 1B illustrates the layer 30, the layer 60, the sealing substrate 40, and the like that are spaced from one another.

The semiconductor device 100A includes a display portion driver circuit 23. In the structure illustrated in FIG. 1A, the display portion driver circuit 23 includes a circuit portion 23a and a circuit portion 23b.

In FIG. 1A, the layer 30 includes the circuit portion 23a and a terminal portion 29. An FPC (Flexible printed circuits) 29a is electrically connected to the terminal portion 29, and the circuit portion 23b is placed over the FPC 29a.

The layer 60 is provided to be overlapped with the region 31a included in the layer 30. The layer 60 includes a plurality of light-emitting elements 61, and the emission luminance of each of the plurality of light-emitting elements 61 is controlled by each of a plurality of pixel circuits 51 provided in the region 31a. The pixel circuits 51 and the light-emitting elements 61 will be described later.

The circuit portion 23a functions as, for example, a scan line driver circuit. The circuit portion 23b functions as, for example, a signal line driver circuit.

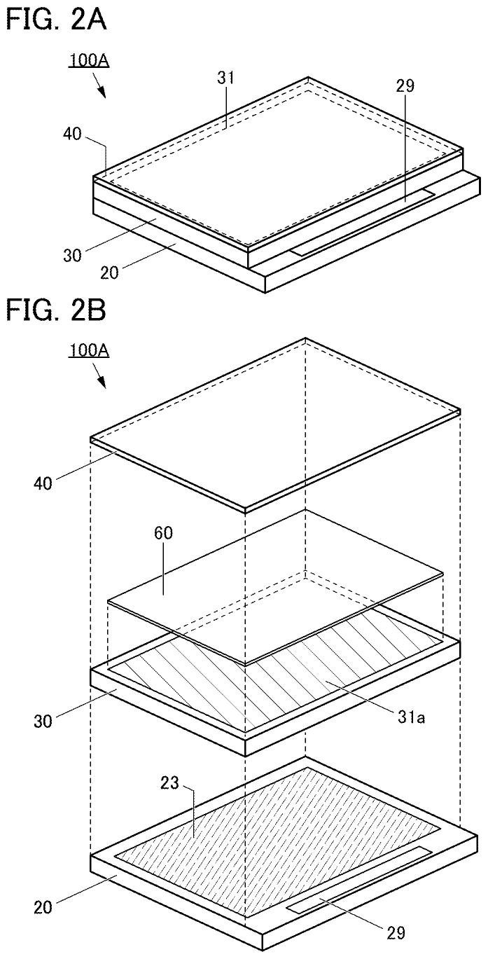

FIG. 2A illustrates a structure where the semiconductor device 100A includes a layer 20.

The semiconductor device 100A illustrated in FIG. 2A includes the layer 20, the layer 30, and the sealing substrate 40 over the layer 30. The semiconductor device 100A includes the display portion 31, and the display portion 31 includes the region 31a provided in the layer 30 and the layer 60. The region 31a includes a plurality of pixel circuits arranged in a matrix. The layer 30 is provided with the region 31a, and the layer 60 is provided between the sealing substrate 40 and the region 31a. For easy understanding of the structure of the semiconductor device 100A illustrated in FIG. 2A, FIG. 2B illustrates the layer 20, the layer 30, the layer 60, the sealing substrate 40, and the like that are spaced from one another.

The layer 20 includes the display portion driver circuit 23 and the terminal portion 29.

The display portion driver circuit 23 is electrically connected to the display portion 31 and has a function of supplying image data to a pixel circuit included in the display portion 31. A variety of circuits such as a shift register, a level shifter, an inverter, a latch, an analog switch, and a logic circuit can be used as the display portion driver circuit 23.

The layer 20 preferably includes a transistor using a single crystal semiconductor substrate such as a single crystal silicon substrate.

When the display portion driver circuit 23 and the display portion 31 are stacked, downsizing of the semiconductor device 100A is possible. In addition, when the display portion driver circuit 23 is provided to be overlapped with the display portion 31, the bezel width of a periphery of the display portion 31 can be made extremely narrow; therefore, the area of the display portion 31 can be expanded. Thus, the resolution of the display portion 31 can be increased. Consequently, the display quality of the semiconductor device 100A can be increased.

In addition, in the case where the resolution of the display portion 31 is constant, the area occupied by one pixel can be increased. Thus, the emission luminance of the display portion 31 can be increased. Furthermore, the pixel aperture ratio can be increased. For example, the pixel aperture ratio can be greater than or equal to 40% and less than 100%, preferably greater than or equal to 50% and less than or equal to 95%, further preferably greater than or equal to 60% and less than or equal to 95%. Moreover, by the expansion of the area occupied by one pixel, the density of current supplied to pixels can be lowered. Accordingly, a load on the pixels is reduced, so that the reliability of the semiconductor device 100A can be increased.

In addition, when the display portion driver circuit 23 and the pixel circuits included in the display portion 31 are stacked, wirings for electrically connecting the display portion driver circuit 23 and the pixel circuits included in the display portion 31 to each other can be shortened. Thus, wiring resistance and parasitic capacitance can be reduced, and the operation speed of the semiconductor device 100A can be increased. Furthermore, the power consumption of the semiconductor device 100A is reduced.

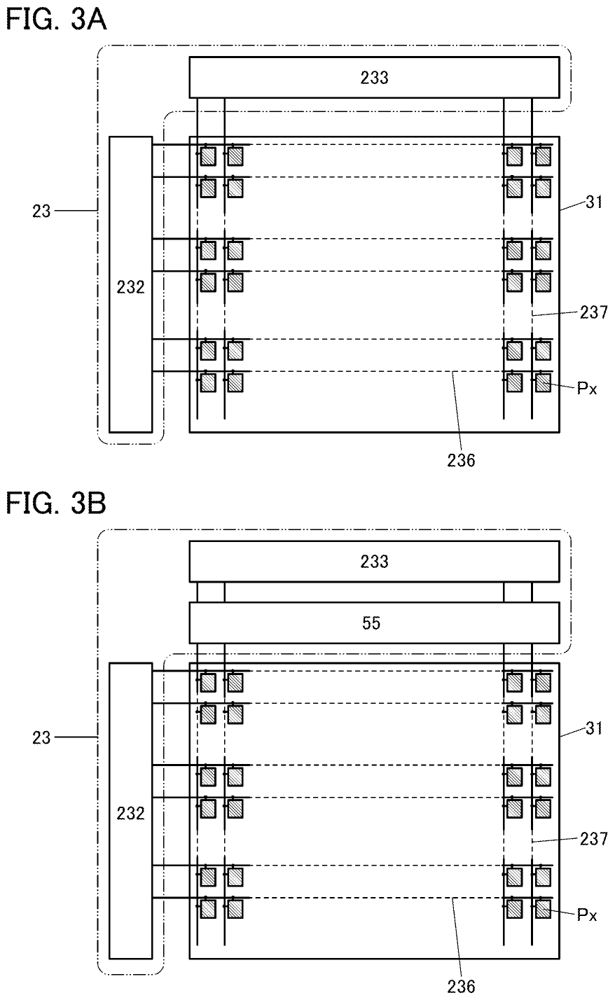

FIG. 3A is a block diagram illustrating the display portion driver circuit 23 and the display portion 31.

The display portion driver circuit 23 includes a first driver circuit 232 and a second driver circuit 233. A circuit included in the first driver circuit 232 functions as, for example, a scan line driver circuit. A circuit included in the first driver circuit 232 functions as, for example, a signal line driver circuit. Note that some sort of circuit may be provided at a position facing the first driver circuit 232 with the display portion 31 therebetween. Some sort of circuit may be provided at a position facing the second driver circuit 233 with the display portion 31 therebetween.

Note that the display portion driver circuit 23 is referred to as a “peripheral driver circuit” in some cases. A variety of circuits such as a shift register, a level shifter, an inverter, a latch, an analog switch, and a logic circuit can be used as the peripheral driver circuit. In the peripheral driver circuit, a transistor, a capacitor, and the like can be used.

In addition, the display portion 31 includes m wirings 236 that are arranged substantially parallel to each other and whose potentials are controlled by the circuit included in the first driver circuit 232, n wirings 237 that are arranged substantially parallel to each other and whose potentials are controlled by the circuit included in the second driver circuit 233, and a plurality of pixels Px that are arranged in a matrix. The wiring 236 is electrically connected to the first driver circuit 232. The wiring 237 is electrically connected to the second driver circuit 233. For example, each of the plurality of pixels Px is electrically connected to any of the m wirings 236. Furthermore, for example, each of the plurality of pixels Px is electrically connected to any of the n wirings 237.

Note that as illustrated in FIG. 3B, the display portion driver circuit 23 may include a protection circuit 55. In a structure illustrated in FIG. 3B, an example where the protection circuit 55 is provided between the second driver circuit 233 and the display portion 31 is illustrated. In addition, although not illustrated, a protection circuit may be provided between the first driver circuit 232 and the display portion 31.

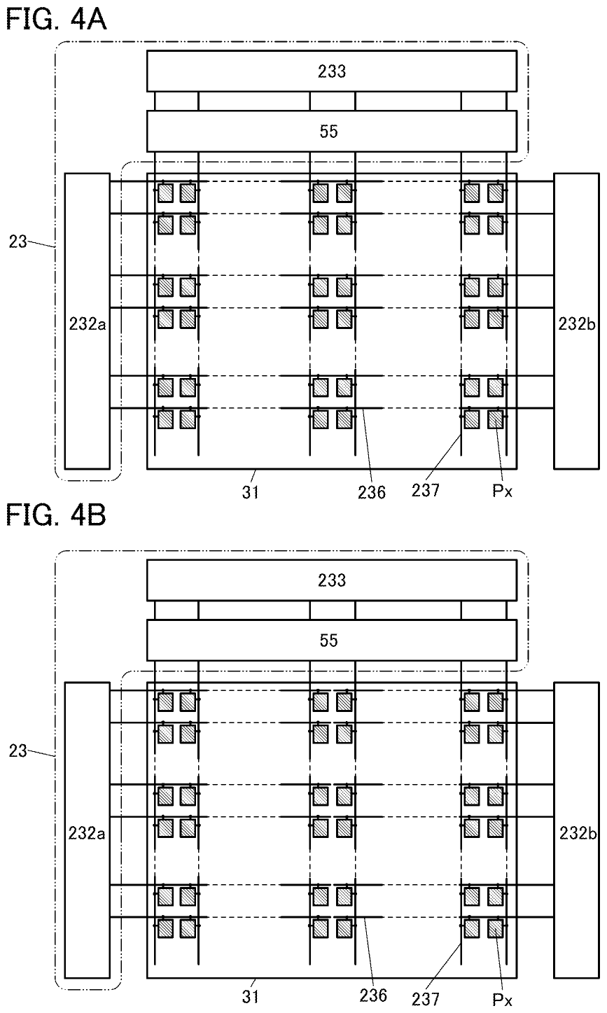

Alternatively, as illustrated in FIG. 4A, pixels Px where the positions of wirings 237 are inverted horizontally may be included in the pixels Px arranged in a matrix.

In addition, FIG. 4A and FIG. 4B each illustrate an example where the first driver circuits 232 are arranged on both sides with the display portion 31 therebetween. The first driver circuit 232 provided on the left side is sometimes referred to as a first driver circuit 232a, and the first driver circuit 232 provided on the right side is sometimes referred to as a first driver circuit 232b. In the case where the first driver circuits 232 are arranged on both sides with the display portion 31 therebetween, as illustrated in FIG. 4B, a structure may be employed in which wirings 236 electrically connected to the first driver circuit 232a and wirings 236 electrically connected to the first driver circuit 232b are separated from each other. In such a case, for example, light exposure is performed so that a region between a region of pixels Px electrically connected to the first driver circuit 232a and a region of pixels Px electrically connected to the first driver circuit 232b corresponds to a boundary between regions for division light exposure to be described later.

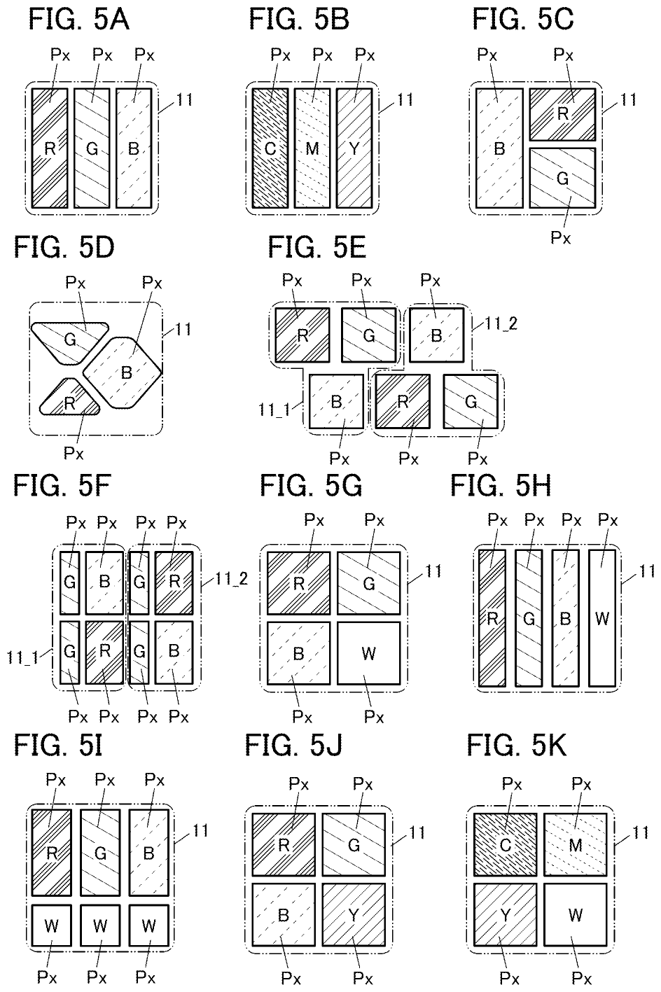

Among the plurality of pixels Px included in the display portion 31, for example, a pixel Px that includes a light-emitting element exhibiting red light, a pixel Px that includes a light-emitting element exhibiting green light, and a pixel Px that includes a light-emitting element exhibiting blue light collectively function as one pixel 11 and the emission amount (emission luminance) of each of the pixels Px is controlled, so that full-color display can be achieved. Thus, the three pixels Px each function as a subpixel. That is, three subpixels control the emission amount or the like of red light, green light, and blue light (see FIG. 5A). Note that the colors of light controlled by the three subpixels are not limited to a combination of red (R), green (G), and blue (B), and may be cyan (C), magenta (M), and yellow (Y) (see FIG. 5B). In addition, the three subpixels do not necessarily have the same area. In the case where luminous efficiency, reliability, or the like varies depending on an emission color, the subpixel area may be changed depending on the emission color (see FIG. 5C). The pixel 11 illustrated in FIG. 5(C) includes a subpixel B across an upper row (a first row) and a lower row (a second row) of a first column, includes a subpixel R in an upper row (a first row) of a second column, and includes a subpixel G in a lower row (a second row) of the second column. Note that a structure with subpixel arrangement illustrated in FIG. 5C may be referred to as “S-stripe arrangement.”

FIG. 5D illustrates an example of the pixel 11 that includes the subpixel G whose top surface has a rough trapezoidal shape with rounded corners, the subpixel R whose top surface has a rough triangle shape with rounded corners, and the subpixel B whose top surface has a rough tetragonal or rough hexagonal shape with rounded corners. In addition, the subpixel G has a larger light-emitting area than the subpixel R In this manner, the shapes and sizes of the subpixels can be determined independently. For example, the size of a subpixel including a light-emitting device with higher reliability can be made smaller. For example, the subpixel R may be a red subpixel, the subpixel G may be a green subpixel, and the subpixel B may be a blue subpixel.

Delta arrangement is employed in a pixel 11_1 and a pixel 11_2 illustrated in FIG. 5E. The pixel 11_1 includes two subpixels (the subpixels R and G) in an upper row (a first row) and one subpixel (the subpixel B) in a lower row (a second row). The pixel 11_2 includes one subpixel (the subpixel B) in the upper row (the first row) and two subpixels (the subpixels R and G) in the lower row (the second row). Although FIG. 5F illustrates an example where the subpixels each have a top surface having a rough tetragonal shape with rounded corners, the subpixels may each have a top surface having a circular shape, for example.

Alternatively, PenTile arrangement illustrated in FIG. 5F may be used.

Note that the arrangement of the subpixels, for example, the arrangement of the subpixels R, the arrangement of the subpixels G, and the arrangement of the subpixels B may be interchanged with each other.

Alternatively, four subpixels may collectively function as one pixel. For example, a subpixel that controls white light (W) may be added to the three subpixels that control red light, green light, and blue light (see FIG. 5G). The addition of the subpixel that controls white light can increase the luminance of a display region.

FIG. 5G illustrates an example where four subpixels, subpixels R, G, B, and W each having a substantially square shape are arranged in a matrix, two subpixels (the subpixels R and G) are included in an upper row (a first row), and two subpixels (the subpixels B and W) are included in a lower row (a second row).

Alternatively, as illustrated in FIG. 5H, the four subpixels, the subpixels R, G, B, and W may be arranged in stripes. Alternatively, as illustrated in FIG. 5I, the subpixels R, G, and B that are arranged in stripes in an upper row (a first row) may be included, and one subpixel W may be included for each column in a lower row (a second row).

Alternatively, a subpixel that controls yellow light may be added to the three subpixels that control red light, green light, and blue light (see FIG. 5J). Alternatively, a subpixel that controls white light may be added to the three subpixels that control cyan light, magenta light, and yellow light (see FIG. 5K).

When the number of subpixels functioning as one pixel is increased and subpixels that control light of red, green, blue, cyan, magenta, yellow, and the like are used in an appropriate combination, reproducibility of halftones can be increased. Therefore, color reproducibility can be increased.

In addition, the display device according to one embodiment of the present invention can reproduce the color gamut of various standards. For example, the display device according to one embodiment of the present invention can reproduce the color gamut of the PAL (Phase Alternating Line) standard and the NTSC (National Television System Committee) standard used for TV broadcasting; the sRGB (standard RGB) standard and the Adobe RGB standard widely used for display devices used in electronic devices such as personal computers, digital cameras, and printers; the ITU-R BT.709 (International Telecommunication Union Radiocommunication Sector Broadcasting Service (Television) 709) standard used for HDTV (High Definition Television, also referred to Hi-Vision); the DCI-P3 (Digital Cinema Initiatives P3) standard used for digital cinema projection; the ITU-R BT.2020 (REC.2020 (Recommendation 2020)) standard used for UHDTV (Ultra High Definition Television, also referred to as Super Hi-Vision); and the like.

In addition, by arranging the pixels 11 in a matrix of 1920×1080, the display portion 31 that can perform full-color display with a resolution of what is called full high definition (also referred to as “2K resolution,” “2K1K,” “2K,” or the like) can be achieved. Alternatively, for example, by arranging the pixels 11 in a matrix of 3840×2160, the display portion 31 that can perform full-color display with a resolution of what is called ultra-high definition (also referred to as “4K resolution,” “4K2K,” “4K,” or the like) can be achieved. Alternatively, for example, by arranging the pixels 11 in a matrix of 7680×4320, the display portion 31 that can perform full-color display with a resolution of what is called super high definition (also referred to as “8K resolution,” “8K4K,” “8K,” or the like) can be achieved. By increasing the number of pixels 11, the display portion 31 that can perform full-color display with 16K and 32K resolution can also be achieved.

In addition, the pixel density (definition) of the display portion 31 is preferably higher than or equal to 1000 ppi and lower than or equal to 10000 ppi. For example, the definition may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 31. For example, the display portion 31 of the semiconductor device 100A is compatible with a variety of screen ratios such as 1:1 (a square), 4:3, 16:9, and 16:10.

Note that in the case where the semiconductor device 100A is used as a display device for XR, the display portion 31 can have a screen diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 31 may have a screen diagonal size of 1.5 inches or around 1.5 inches.

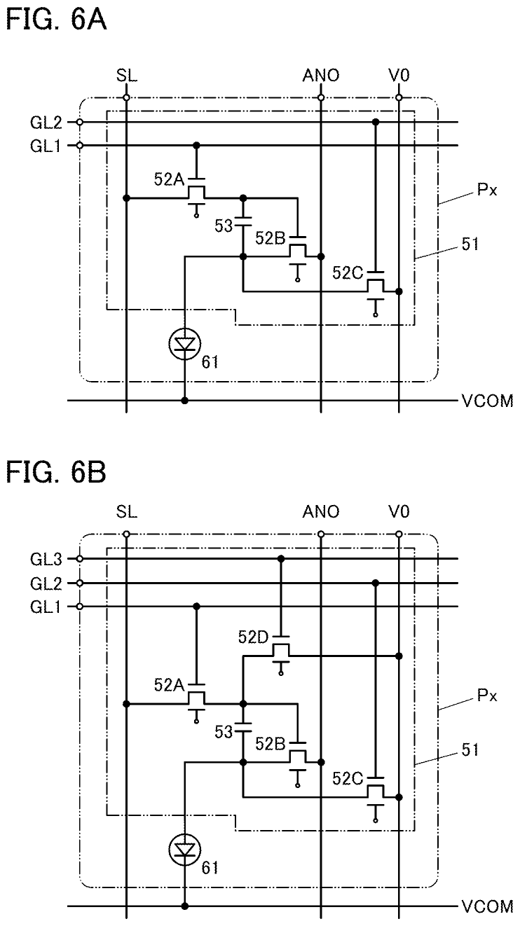

FIG. 6A illustrates a circuit structure example of the pixel Px. The pixel Px includes the pixel circuit 51 and the light-emitting element 61.

The pixel circuit 51 illustrated as an example in FIG. 6A includes a transistor 52A, a transistor 52B, a transistor 52C, and a capacitor 53. Each of the transistor 52A, the transistor 52B, and the transistor 52C can be formed using a transistor including an oxide semiconductor in a channel formation region (hereinafter such a transistor is referred to as an “OS transistor”). Each of the OS transistors, the transistor 52A, the transistor 52B, and the transistor 52C, preferably includes a back gate electrode, in which case a structure in which the back gate electrode is supplied with the same signal as that supplied to a gate electrode or a structure in which the back gate electrode is supplied with a signal different from that supplied to the gate electrode can be used.

The transistor 52B includes a gate electrode electrically connected to the transistor 52A, a first terminal electrically connected to the light-emitting element 61, and a second terminal electrically connected to a wiring ANO. The wiring ANO is a wiring for supplying a potential for supplying current to the light-emitting element 61.

The transistor 52A includes a first terminal electrically connected to the gate electrode of the transistor 52B, a second terminal electrically connected to a wiring SL that functions as a source line, and a gate electrode having a function of controlling its conduction state or non-conduction state on the basis of the potential of a wiring GL1 that functions as a gate line.

The transistor 52C includes a first terminal electrically connected to a wiring V0, a second terminal electrically connected to the light-emitting element 61, and a gate electrode having a function of controlling its conduction state or non-conduction state on the basis of the potential of a wiring GL2 that functions as a gate line. The wiring V0 is a wiring for supplying a reference potential and a wiring for outputting current flowing through the pixel circuit 51 to the display portion driver circuit 23.

The capacitor 53 includes a conductive film electrically connected to the gate electrode of the transistor 52B and a conductive film electrically connected to a second electrode of the transistor 52C.

The light-emitting element 61 includes a first electrode electrically connected to the first electrode of the transistor 52B and a second electrode electrically connected to a wiring VCOM. The wiring VCOM is a wiring for supplying a potential for supplying current to the light-emitting element 61.

Accordingly, the intensity of light emitted from the light-emitting element 61 can be controlled in accordance with an image signal supplied to the gate electrode of the transistor 52B. Furthermore, variations in the gate-source potential of the transistor 52B can be inhibited by the reference potential of the wiring V0 supplied through the transistor 52C.

In addition, a current value that can be used for setting of pixel parameters can be output from the wiring V0. More specifically, the wiring V0 can function as a monitor line for outputting current flowing through the transistor 52B or current flowing through the light-emitting element 61 to the outside. Current output to the wiring V0 may be converted into voltage by a source follower circuit or the like.

Note that the light-emitting element described in one embodiment of the present invention refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

The pixel Px illustrated in FIG. 6B includes a transistor 52D and a wiring GL3 in addition to FIG. 6A. The transistor 52D can be formed using an OS transistor. In the case where the transistor 52D is formed using an OS transistor, the transistor 52D preferably includes a back gate electrode, in which case a structure in which the back gate electrode is supplied with the same signal as that supplied to a gate electrode or a structure in which the back gate electrode is supplied with a signal different from that supplied to the gate electrode can be used.

The transistor 52D includes the gate electrode electrically connected to the wiring GL3, a first terminal electrically connected to the first terminal of the transistor 52A, and a second terminal electrically connected to the wiring V0.

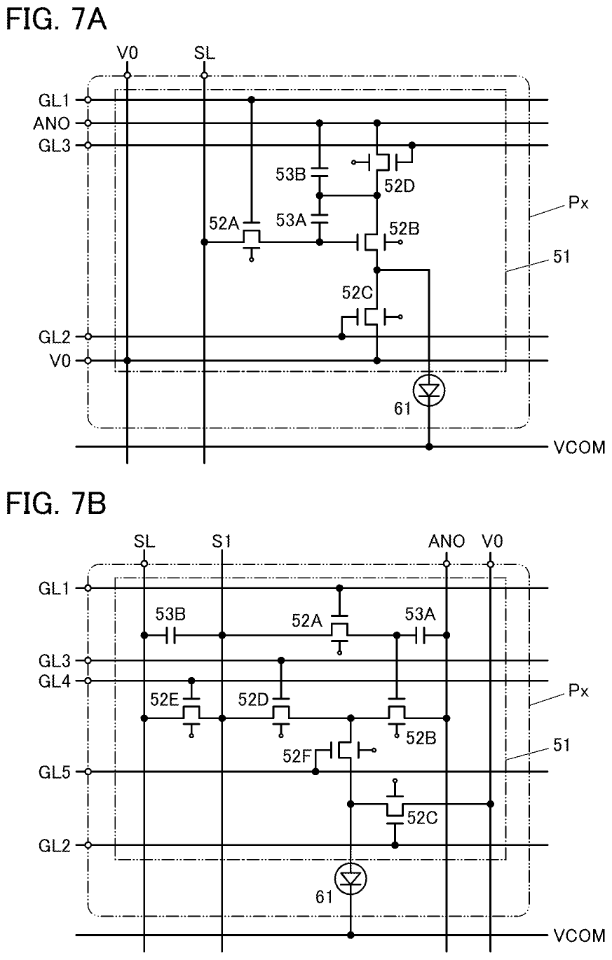

The pixel Px illustrated in FIG. 7A includes the transistors 52A, 52B, 52C, and 52D, a capacitor 53A, and a capacitor 53B.

The arrangement of the transistor 52D in the pixel Px illustrated in FIG. 7A differs from that in FIG. 6B. The transistor 52D is placed between the transistor 52B and the wiring ANO. The gate electrode of the transistor 52D is electrically connected to the wiring GL3. The first terminal of the transistor 52D is electrically connected to the second terminal of the transistor 52B. The second terminal of the transistor 52D is electrically connected to the wiring ANO.

In addition, the pixel Px illustrated in FIG. 7A differs from that in FIG. 6B in that the capacitors 53A and 53B are included instead of the capacitor 53. The capacitor 53A includes a conductive film electrically connected to the gate electrode of the transistor 52B and a conductive film electrically connected to the second terminal of the transistor 52B. The capacitor 53B includes a conductive film electrically connected to the second terminal of the transistor 52B and a conductive film electrically connected to the wiring ANO.

The pixel Px illustrated in FIG. 7B includes transistors 52A, 52B, 52C, 52D, 52E, and 52F, the capacitor 53A, and the capacitor 53B. In addition, the pixel Px illustrated in FIG. 7B is electrically connect to five wirings, the wiring GL1 to a wiring GL5, the wiring SL, the wiring V0, the wiring ANO, and a wiring S1. A signal is supplied to the wiring S1, for example.

In FIG. 7B, the transistor 52B includes the gate electrode electrically connected to the transistor 52A, the first terminal electrically connected to the transistor 52F, and the second terminal electrically connected to the wiring ANO.

The transistor 52A includes the gate electrode electrically connected to the wiring GL1, the first terminal electrically connected to the gate electrode of the transistor 52B, and the second terminal electrically connected to the wiring S1.

The transistor 52C includes the gate electrode electrically connected to the wiring GL2, the first terminal electrically connected to the wiring V0, and the second terminal electrically connected to the light-emitting element 61.

The transistor 52D includes the gate electrode electrically connected to the wiring GL3, the first terminal electrically connected to the wiring S1, and the second terminal electrically connected to the transistor 52F.

The transistor 52E includes a gate electrode electrically connected to the wiring GL4, a first terminal electrically connected to the wiring S1, and a second terminal electrically connected to the wiring SL.

The transistor 52F includes a gate electrode electrically connected to the wiring GL5, a first terminal electrically connected to the light-emitting element 61, and a second terminal electrically connected to the transistor 52B and the transistor 52D.

The capacitor 53A includes a conductive film electrically connected to the wiring ANO and a conductive film electrically connected to the gate electrode of the transistor 52B.

The capacitor 53B includes a conductive film electrically connected to the wiring SL and a conductive film electrically connected to the wiring S1.

### [Structure Example 1 of Display Portion]

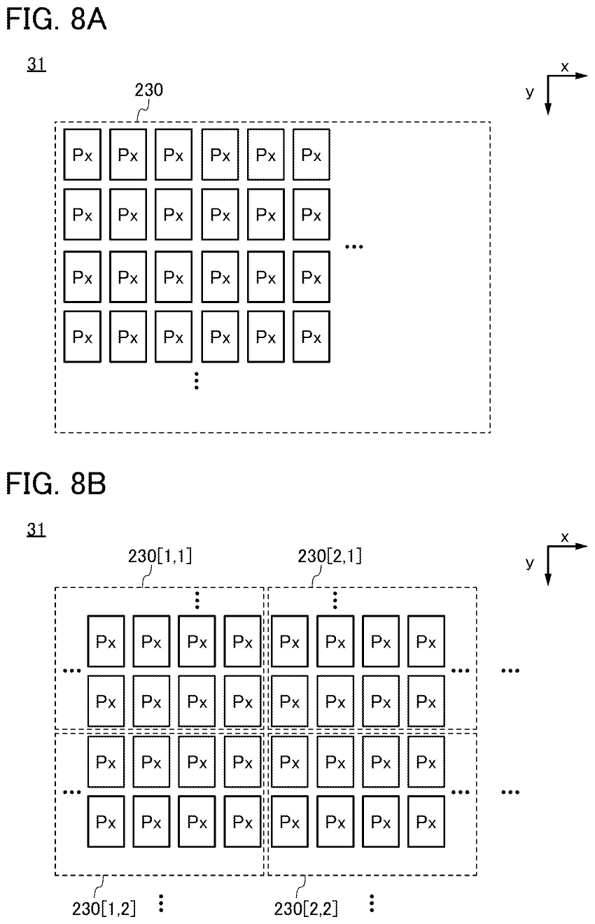

A plurality of pixels Px arranged in a matrix in the display portion 31 are referred to as a pixel matrix 230. FIG. 8A illustrates an example of a plan view of the pixel matrix 230 included in the display portion 31. The pixel matrix 230 includes the plurality of pixels Px arranged in a matrix.

The patterns of layers such as a semiconductor layer and a conductive layer of the plurality of pixels Px included in the pixel matrix 230 can be formed using a light exposure apparatus. The area of single light exposure in the light exposure apparatus is sometimes smaller than the area of the pixel matrix 230. In such a case, for formation of the pattern of each layer included in the pixel matrix 230, the entire light exposure can be performed by performing light exposure on a plurality of divided light exposure regions and putting the light exposure regions together. Such light exposure is referred to as division light exposure in some cases. In a region where the light exposure regions are put together, some of two adjacent light exposure regions are preferably overlapped with each other.

When the light exposure regions are put together using division light exposure, high-definition light exposure can be performed in a wide area. Thus, for example, even in the case where a light exposure apparatus for LSI, typically, a scanner apparatus is used and the definition is increased by setting the thickness of each pattern or an interval between patterns to less than or equal to 500 nm, less than or equal to 200 nm, less than or equal to 100 nm, less than or equal to 50 nm, or less than or equal to 30 nm, the diagonal size of the display portion 31 can be easily increased. More specifically, for example, the diagonal size of the display portion 31 can be easily made greater than or equal to 1 inch, for example.

In addition, for example, even in the case where the pixel density (definition) of the display device according to one embodiment of the present invention is increased, specifically, even in the case where the pixel density (definition) is made higher than or equal to 300 ppi, preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, or yet further preferably higher than or equal to 7000 ppi, the diagonal size of the display portion 31 can be easily increased. More specifically, the diagonal size of the display portion 31 can be easily made greater than or equal to 1 inch, for example.

FIG. 8B illustrates an example where a pixel matrix is divided into a plurality of regions. The pixel matrix included in the display portion 31 can be divided into regions denoted by pixel submatrices 230[k,m]. Here, each of k and m is a positive integer, where k is a coordinate in an x direction and m is a coordinate in a y direction. A single light exposure region can be each of the divided pixel submatrices 230[k,m].

An example of two pixels where a first wiring and a second wiring are placed to be adjacent to each other is shown. Note that in this specification and the like, in the case where two wirings are adjacent to each other, the expression “the two wirings approximate to each other” is used in some cases.

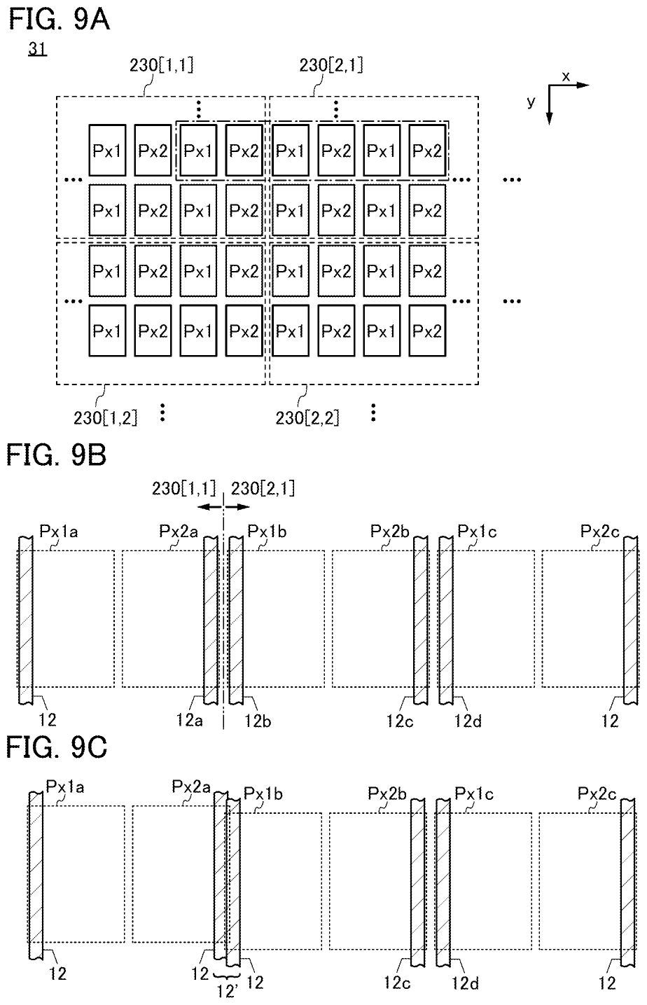

In two pixels that are adjacent to each other in the x direction in a plan view, when one wirings included in the two pixels are placed to exhibit line symmetry with an axis facing a y-axis direction used as a symmetrical axis, these wirings included in the pixels can be placed to be adjacent to each other. A specific example is described using FIG. 9B. FIG. 9B is an enlarged view of a region surrounded by a dashed-dotted line in FIG. 9A.

FIG. 9A illustrates an example where the pixel matrix 230 in the structure illustrated in FIG. 8B includes two kinds of pixels Px (hereinafter sometimes referred to as a pixel Px1 and a pixel Px2). In FIG. 9A, the pixel matrix 230 includes a plurality of pixels Px1 and a plurality of pixels Px2. The pixel Px1 and the pixel Px2 differ from each other in the arrangement of one or more wirings.

The pixel matrix 230 includes a plurality of pixel submatrices. In the pixel Px and the pixel Px2 adjacent to each other with a boundary of adjacent pixel submatrices therebetween, one wirings included in the pixel Px1 and the pixel Px2 are placed to be adjacent to each other.

In a plurality of pixel submatrices 230[k,m] included in the display portion 31 illustrated in FIG. 9A, each of the pixel submatrices 230[k,m] includes a plurality of pixels Px1 and a plurality of pixels Px2, the pixels Px1 and the pixels Px2 are alternately arranged along the x direction, and the same pixels are arranged along the y direction.

Note that arranging the pixels along the x direction is not limited to arranging the pixels along a positive x direction. The pixels may be arranged along a negative x direction. In addition, arranging the pixels along the y direction is not limited to arranging the pixels along a positive y direction. The pixels may be arranged along a negative y direction. Furthermore, FIG. 8A or the like illustrates an example in which an x-axis and a y-axis are orthogonal to each other; however, the x-axis and the y-axis may be oblique to each other.

As each of the pixel Px and the pixel Px2, the subpixels R, G, B, W, C, M, Y, and the like described above can be employed, for example. Note that in the case where one of the subpixels R, G, B, W, C, M, Y, and the like is selected as the pixel Px1, a subpixel may be selected, as the pixel Px2, from the subpixels R, G, B, W, C, M, Y, and the like other than the subpixel that is selected as the pixel Px1, or the same subpixel as the pixel Px1 may be selected.

FIG. 9B is an enlarged view of a region surrounded by a dashed-dotted line square in FIG. 9A and illustrates six pixels arranged according to two adjacent pixel submatrices 230[k,m](here, a pixel submatrix 230[1,1] and a pixel submatrix 230[2,1]) in the x direction. Here, the pixel Px1, the pixel Px2, the pixel Px1, the pixel Px2, the pixel Px1, and the pixel Px2 sequentially arranged along the x direction are referred to as a pixel Px1a, a pixel Px2a, a pixel Pxb, a pixel Px2b, a pixel Pxc, and a pixel Px2c, respectively.

The pixel Pxa and the pixel Px2a are included in the pixel submatrix 230[1,1], and the pixel Px1b, the pixel Px2b, the pixel Pxc, and the pixel Px2c are included in the pixel submatrix 230[2,1]. Light exposure is separately performed on the pixel submatrix 230[1,1] and the pixel submatrix 230[2,1]. The pixel Px2a and the pixel Px1b are adjacent to each other with a boundary of light exposure regions therebetween. In addition, the pixel Px2b and the pixel Px1c are adjacent to each other in the pixel submatrix 230[2,1].

In addition, in the structure example illustrated in FIG. 9B, each pixel Px includes a wiring 12. The wiring 12 is a wiring that extends in the y direction. Furthermore, the wiring 12 is provided across the plurality of pixels Px arranged in the y direction and is shared by the plurality of pixels Px.

In a plan view, the arrangement of the wiring 12 in the pixel Px1 and the arrangement of the wiring 12 in the pixel Px2 exhibit line symmetry with an axis facing the y-axis direction used as a symmetrical axis. In addition, the wiring 12 included in the pixel Px2a (hereinafter sometimes referred to as a wiring 12a) and the wiring 12 included in the pixel Px1b (hereinafter sometimes referred to as a wiring 12b) are placed to be adjacent to each other. Furthermore, the wiring 12 included in the pixel Px2b (hereinafter sometimes referred to as a wiring 12c) and the wiring 12 included in the pixel Px1c (hereinafter sometimes referred to as a wiring 12d) are placed to be adjacent to each other.

Here, the wirings placed to exhibit line symmetry do not necessarily exhibit line symmetry in the whole of each of the pixels including the wirings as long as of the wirings are placed to partly exhibit line symmetry.

Specifically, for example, in the case where the display portion according to one embodiment of the present invention includes a first pixel and a second pixel that are adjacent to each other with a boundary of adjacent pixel submatrices therebetween, the first pixel includes a first wiring, the second pixel includes a second wiring, and the first wiring and the second wiring are placed to be adjacent to each other, an area of greater than or equal to 30% of the first wiring included in the first pixel and the second wiring are placed to exhibit line symmetry with respect to an axis facing the y-axis direction.

In addition, the first wiring and the second wiring are not necessarily placed to exhibit line symmetry as long as the first wiring and the second wiring are adjacent to each other.

Signals supplied to the wirings 12 are preferably the same in two pixels where the wirings 12 are placed to be adjacent to each other. In addition, signals supplied to the wirings 12 may be the same in all the pixels included in the display portion 31.

In adjacent light exposure regions, light exposure misalignment sometimes occurs. Due to the misalignment, in some cases, a distance between two pixels Px that are adjacent to each other in the x direction becomes shorter with a boundary of the light exposure regions therebetween, and wirings, conductive layers, semiconductor layers, and the like included in the pixels are overlapped with each other and are short-circuited.

In the display device according to one embodiment of the present invention, even in the case where light exposure misalignment occurs, malfunction of the display device can be inhibited by a structure where the same signal is supplied to wirings, conductive layers, semiconductor layers, and the like that easily cause short circuit.

FIG. 9C illustrates an example where a distance between two pixels Px adjacent to each other in the x direction with a boundary of light exposure regions therebetween is made shorter than a distance between two adjacent pixels Px in the same pixel submatrix 230[k,m] due to misalignment and the wiring 12 of the pixel Px2a and the wiring 12 of the pixel Px1b are overlapped with each other. The wiring 12 of the pixel Px2a and the wiring 12 of the pixel Px1b are sometimes short-circuited due to the overlap; however, when the same signal is supplied to the wirings 12 in the pixel Px2a and the pixel Px1b, each pixel Px can operate correctly.

In addition, due to the overlap of the wiring 12 of the pixel Px2a and the wiring 12 of the pixel Px1b, one wide wiring (hereinafter sometimes referred to as a wiring 12′) is formed in some cases. In such a case, the wiring 12′ is provided between the pixel Px2a and the pixel Px1b, and the width of the wiring 12′ is sometimes larger than the width of at least one of the wiring 12c and the wiring 12d.

In addition, even in the case where the wiring 12 of the pixel Px2a and the wiring 12 of the pixel Px1b are overlapped with each other, a distance between the wirings 12 included in the pixels is sometimes shorter than a distance between the wirings 12 included in adjacent pixels Px in the same pixel submatrix. When the distance between the wirings becomes shorter, there is a concern that leakage current occurs between the wirings. Furthermore, when the distance between the wirings becomes shorter, if there is a potential difference between the wirings, capacitance between the wirings becomes larger, which might apply a load to a circuit operation. Even in such a case, when the same signal is supplied to the wirings 12 included in the pixels, each pixel Px can operate correctly.

In the display portion according to one embodiment of the present invention, in two pixels that are adjacent to each other with a boundary of adjacent pixel submatrices therebetween, one wirings included in the pixels are placed to be adjacent to each other. In addition, the same signal is supplied to the wirings that are placed to be adjacent to each other. In this specification and the like, the expression “a wiring A and a wiring B are adjacent to each other” means that a wiring C is not placed between the wiring A and the wiring B, for example. In this specification and the like, in the case where the display portion includes a plurality of wirings and the wiring A and the wiring B are adjacent to each other among the plurality of wirings, the above expression means that another wiring included in the display portion (excluding the wiring A and the wiring B) is not placed between the wiring A and the wiring B.

Alternatively, the display portion according to one embodiment of the present invention includes the first pixel and the second pixel that are adjacent to each other with a boundary of two adjacent pixel submatrices therebetween, the first pixel includes the first wiring, the second pixel includes the second wiring, the first wiring and the second wiring are placed to be adjacent to each other, and the same signal is supplied to the first wiring and the second wiring. Here, the first wiring and the second wiring are wirings for applying a reference potential, for example.

Alternatively, in a plan view, the display portion according to one embodiment of the present invention includes the first pixel and the second pixel that is adjacent to the first pixel in the x direction, the y-axis and the x-axis are orthogonal to each other, and the layout of the first pixel and the layout of the second pixel each have a line-symmetrical structure where an axis facing the y-axis direction is used as a symmetrical axis. The axis facing the y-axis direction refers to, for example, an axis having the same vector as the y-axis. In addition, the axis facing the y-axis direction also refers to the y-axis. Here, pixel layout refers to, for example, arrangement of wirings, electrodes, semiconductor layers, transistors, or capacitors that are included in pixels. The first pixel and the second pixel each include one wiring, and the same signal is supplied to the one wiring included in each pixel. In the case where the layout of the first pixel and the layout of the second pixel each have a line-symmetrical structure, for example, all the components included in the pixels do not necessarily exhibit line symmetry. The one wiring included in each pixel, one transistor electrically connected to the one wiring, and a wiring functioning as a source line preferably exhibit line symmetry.

Here, in the case where the layout of the first pixel and the layout of the second pixel exhibit line symmetry with an axis facing the y-axis direction used as a symmetrical axis in a plan view, the expression “the components included in the first pixel and the second pixel are inverted from each other with respect to the axis facing the y-axis direction” is used in some cases.

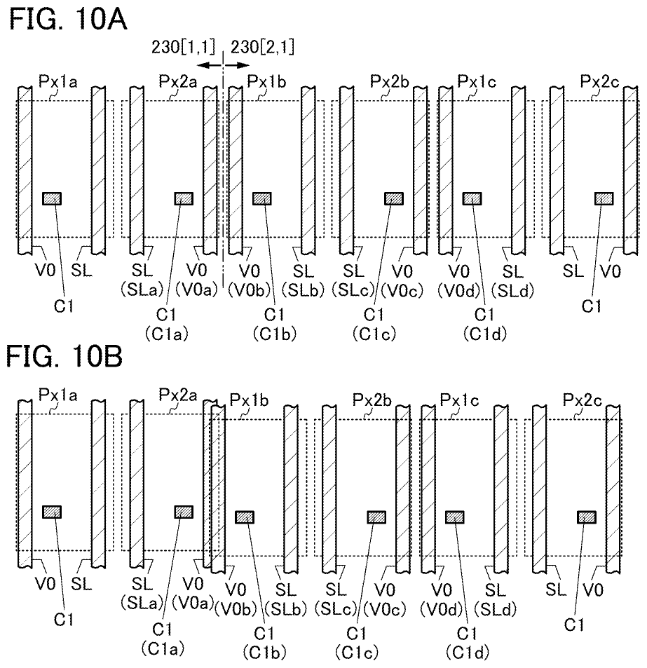

As the wiring 12, specifically, the wiring V0 illustrated in FIG. 6A, FIG. 6B, or the like can be employed, for example. FIG. 10A and FIG. 10B illustrate examples in which the wirings V0 are used as the wirings 12 in FIG. 9B and FIG. 9C, respectively. Here, the wirings V0 included in the pixel Px2a, the pixel Px1b, the pixel Px2b, and the pixel Px1c are referred to as a wiring V0a, a wiring V0b, a wiring V0c, and a wiring V0d, respectively.

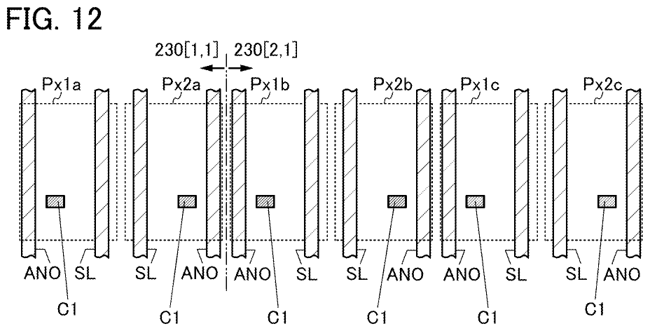

Alternatively, as illustrated in FIG. 12, the wiring ANO illustrated in FIG. 6A or the like may be employed as each of the wirings 12.

In addition, FIG. 10A and FIG. 10B illustrate semiconductor layers C1 that are included in pixels Px. The semiconductor layer C1 includes a channel formation region of a transistor included in the pixel Px. For example, the semiconductor layer C1 can be used as a layer including a channel formation region of the transistor 52A, the transistor 52B, the transistor 52C, or the transistor 52D illustrated in FIG. 6A, FIG. 6B, or the like.

Here, the semiconductor layers C1 included in the pixel Px2a, the pixel Px1b, the pixel Px2b, and the pixel Px1c are referred to as a semiconductor layer C1a, a semiconductor layer Clb, a semiconductor layer C1c, and a semiconductor layer C1d, respectively.

In addition, FIG. 10A and FIG. 10B each illustrate an example in which the pixel Px includes the wiring SL illustrated in FIG. 6A, FIG. 6B, or the like in addition to the wiring V0. Here, the wirings SL included in the pixel Px2a, the pixel Px1b, the pixel Px2b, and the pixel Px1c are referred to as a wiring SLa, a wiring SLb, a wiring SLc, and a wiring SLd, respectively.

A distance between the wiring V0a and the wiring V0b is preferably shorter than a distance between the wiring V0a and the wiring SLb. In addition, the distance between the wiring V0a and the wiring V0b is preferably shorter than a distance between the wiring V0b and the wiring SLa.

The distance between the wiring V0a and the wiring V0b is preferably shorter than a distance between the wiring V0a and the semiconductor layer C1b. In addition, the distance between the wiring V0a and the wiring V0b is preferably shorter than a distance between the wiring V0b and the semiconductor layer C1a.

In addition, the wiring V0a and the wiring V0b are preferably placed between the semiconductor layer C1a and the semiconductor layer C1b. Furthermore, the wiring V0a and the wiring V0b are preferably placed between the wiring SLa and the wiring SLb.

The distance between the wiring V0a and the wiring V0b sometimes differs from a distance between the wiring V0c and the wiring V0d. FIG. 10B illustrates an example in which the distance between the wiring V0a and the wiring V0b is shorter than the distance between the wiring V0c and the wiring V0d and the wiring V0a and the wiring V0b are partly overlapped with each other.

The distance between the wiring V0a and the wiring SLb sometimes differs from a distance between the wiring V0c and the wiring SLd. Furthermore, the distance between the wiring V0a and the semiconductor layer C1b sometimes differs from a distance between the wiring V0c and the semiconductor layer C1d.

The distance between the wiring V0b and the wiring SLa sometimes differs from a distance between the wiring V0d and the wiring SLc. Furthermore, the distance between the wiring V0b and the semiconductor layer C1a sometimes differs from a distance between the wiring V0d and the semiconductor layer C1c.

The distance between the wiring V0c and the wiring V0d is preferably shorter than the distance between the wiring V0c and the wiring SLd. In addition, the distance between the wiring V0c and the wiring V0d is preferably shorter than the distance between the wiring V0d and the wiring SLc.

The distance between the wiring V0c and the wiring V0d is preferably shorter than the distance between the wiring V0c and the semiconductor layer C1d. In addition, the distance between the wiring V0c and the wiring V0d is preferably shorter than a distance between the wiring V0d and the semiconductor layer C1c.

In addition, the wiring V0c and the wiring V0d are preferably placed between the semiconductor layer C1c and the semiconductor layer C1d. Furthermore, the wiring V0c and the wiring V0d are preferably placed between the wiring SLc and the wiring SLd.

In the case where the semiconductor layer C1 is a layer including the channel formation region of the transistor 52C illustrated in FIG. 6A or FIG. 6B, one of a source and a drain of the transistor 52C is electrically connected to the wiring V0a, and the channel formation region is included in the semiconductor layer C1a. In addition, one of the source and the drain of the transistor 52C included in the pixel Px2b is electrically connected to the wiring V0b, and the channel formation region is included in the semiconductor layer C1b.

In addition, in the case where the pixel Px includes a plurality of transistors, in a plan view, channel formation regions of a plurality of transistors included in the pixel Px2a are preferably not placed between the wiring 12a and the wiring 12b. Furthermore, in a plan view, channel formation regions of a plurality of transistors included in the pixel Px1b are preferably not placed between the wiring 12a and the wiring 12b.

In addition, in a plan view, channel formation regions of a plurality of transistors included in the pixel Px2b are preferably not placed between the wiring 12c and the wiring 12d. Furthermore, in a plan view, channel formation regions of a plurality of transistors included in the pixel Px1c are preferably not placed between the wiring 12c and the wiring 12d.

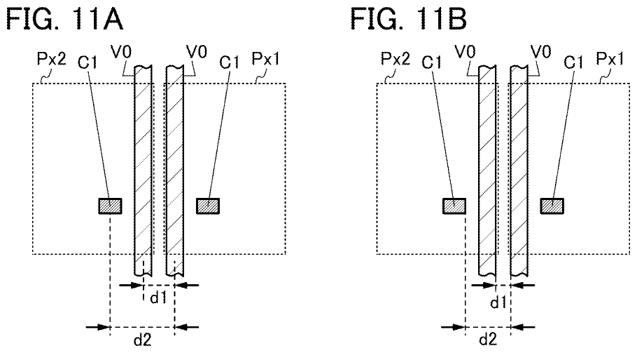

FIG. 11A illustrates an example of a distance d1 between the first wiring (the wiring V0 in FIG. 11A) included in the second pixel (the pixel Px2 in FIG. 11A) and the first wiring included in the first pixel (the pixel Px1 in FIG. 11A) adjacent to the second pixel. In FIG. 11A, the distance d1 is a distance in a direction substantially perpendicular to a direction in which the first wiring extends. In addition, FIG. 11A illustrates an example in which a distance between the centers of the first wirings included in the pixels is measured.

FIG. 11A also illustrates an example of a distance d2 between the semiconductor layer C1 included in the second pixel and the first wiring included in the first pixel. FIG. 11A illustrates an example in which a distance from the center of the semiconductor layer C1 is measured.

In addition, FIG. 11B illustrates an example in which a distance between the first wiring included in the second pixel and an end portion of the first wiring included in the first pixel is measured as the distance d1. For measurement, an end portion that is close to the other object whose distance is to be measured is used. The distance d1 illustrated in FIG. 11B is sometimes referred to as a space between two wirings.

Furthermore, FIG. 11B also illustrates an example in which measurement is performed using an end portion of the semiconductor layer C1 as the distance d2.

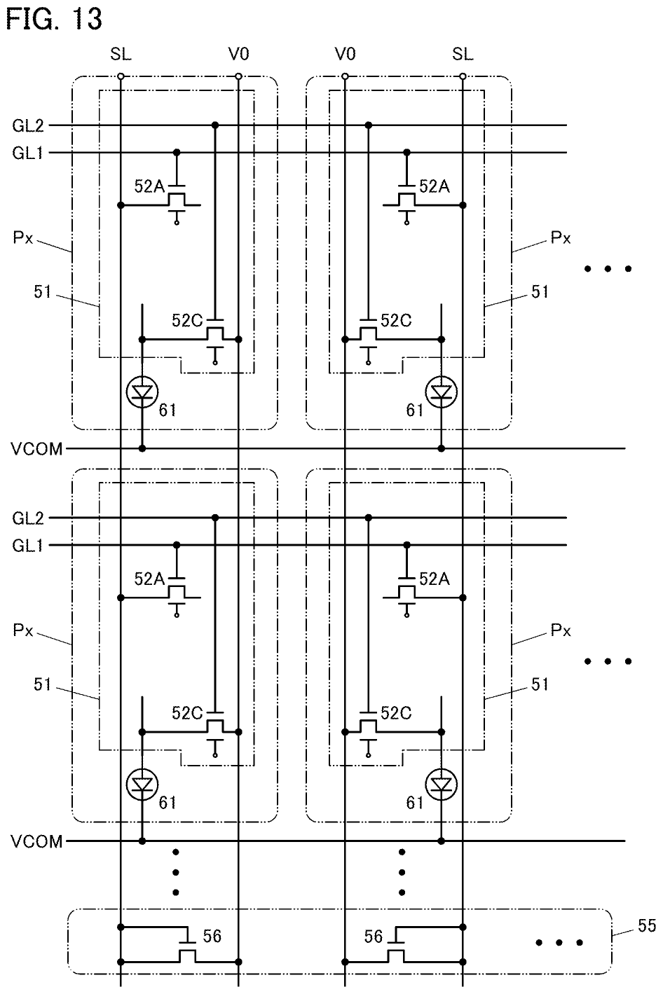

FIG. 13 illustrates an example of a circuit diagram including a plurality of pixels Px, a plurality of wirings GL1, a plurality of wirings GL2, a plurality of wirings SL, a plurality of wirings V0, a plurality of wirings VCOM, and the protection circuit 55. FIG. 13 illustrates an example in which a plurality of pixels Px that are electrically connected to the same wiring V0 and the same wiring SL are electrically connected to one of a plurality of semiconductor elements 56 included in the protection circuit 55. Note that in FIG. 13, for simplification, some components of the pixel circuit 51 are omitted.

In the protection circuit 55, the wirings V0 and the wirings SL are electrically connected to the semiconductor elements 56. FIG. 13 illustrates an example in which a diode-connected transistor is used as each of the semiconductor elements 56; however, one of a variety of elements such as a diode, a transistor, and a resistor can be used, or a plurality of these elements can be used in combination.

In the example of the circuit diagram illustrated in FIG. 13, each of the semiconductor elements 56 is a diode-connected transistor. A gate of the transistor and one of a source and a drain of the transistor are electrically connected to the wiring SL, and the other of the source and the drain of the transistor is electrically connected to the wiring V0.

As illustrated in FIG. 13, two semiconductor elements 56 that are electrically connected to columns of two adjacent pixels, respectively, are sometimes placed to exhibit line symmetry. In addition, two wirings V0 are preferably placed between the two semiconductor elements 56 that are placed to exhibit line symmetry.

Note that although the display portion 31 illustrated in FIG. 9A illustrates an example in which the pixels Px and the pixels Px2 are alternately arranged one by one in the x direction, a plurality of pixels Px1 and a plurality of pixels Px2 may be alternately arranged in the x direction in the display portion 31.

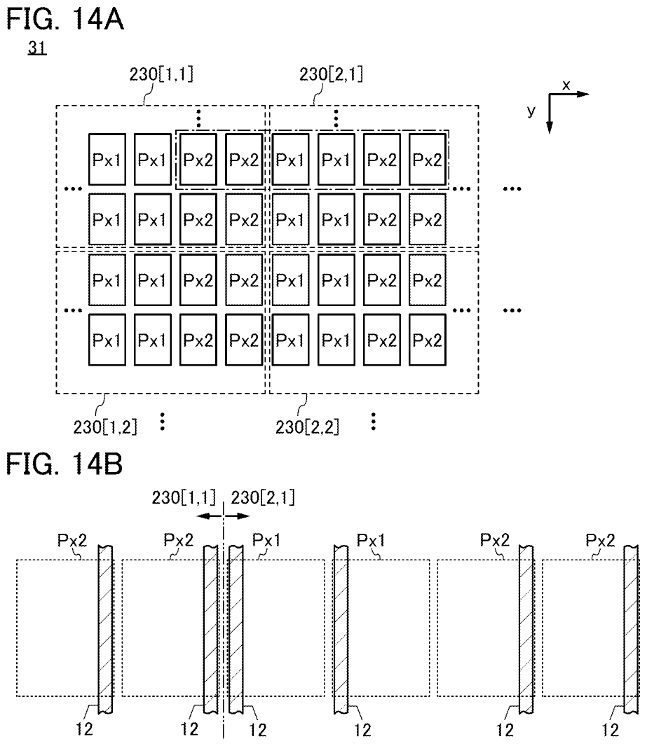

FIG. 14A illustrates an example in which two pixels Px1 and two pixels Px2 are alternately arranged in the x direction. FIG. 14B is an enlarged view of a region surrounded by a dashed-dotted line square in FIG. 14A.

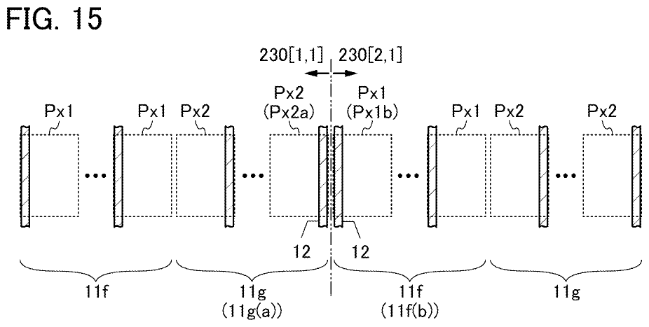

FIG. 15 illustrates an example in which f pixels Px1 (f is an integer greater than or equal to 2) arranged continuously in the x direction and g pixels Px2 (k is an integer greater than or equal to 2) arranged continuously in the x direction are alternately arranged across the pixel submatrix 230[1,1] to the pixel submatrix 230[2,1].

In FIG. 15, pixels 1 if are the f pixels Px1 arranged continuously in the x direction, and pixels 11g are the g pixels Px2 arranged continuously in the x direction. In FIG. 15, the pixels 11g (hereinafter referred to as pixels 11g(a)) and the pixels 11f (hereinafter referred to as pixels 11f(b)) are adjacent to each other with a boundary between the pixel submatrix 230[1,1] and the pixel submatrix 230[2,1] therebetween.

In FIG. 15, among the g pixels Px2 included in the pixels 11g(a), the pixel Px2a is the pixel Px2 that is the closest to the wiring 12 included in the pixel Pxb in a plan view. In addition, among the f pixels Px1 included in the pixels 11f(b), the pixel Px1b is the pixel Px1 that is the closest to the wiring 12 included in the pixel Px2a in a plan view.

For the pixel Px2a and the pixel Px1b illustrated in FIG. 15, the pixel Px2a and the pixel Px1b illustrated in FIG. 9B can be referred to as appropriate.

Although FIG. 9A to FIG. 9C, FIG. 10A, FIG. 10B, FIG. 11A, FIG. 11B, FIG. 14A, FIG. 14B, and FIG. 15 each illustrate the example in which the pixel matrix includes two kinds of pixels Px, the pixel matrix may include three or more kinds of pixels Px.

The case is described in which the display portion according to one embodiment of the present invention includes the first pixel, the second pixel that is adjacent to the first pixel in the positive x direction when seen from the first pixel, and a third pixel that is adjacent to the first pixel in the negative x direction when seen from the first pixel; the first pixel includes the first wiring; the second pixel includes the second wiring; the third pixel includes a third wiring; and the same signal is supplied to the first wiring, the second wiring, and the third wiring. In such a case, for example, the first wiring and the second wiring are placed to be adjacent to each other, the first wiring and the third wiring are not adjacent to each other, and another wiring included in the first pixel and a semiconductor element are placed between the first wiring and the third wiring. In addition, a distance between the first wiring and the second wiring is shorter than a distance between the first wiring and the third wiring.

In addition, the first wiring in the first pixel and the second wiring in the second pixel are preferably placed to exhibit line symmetry with respect to the axis facing the y-axis direction. Furthermore, the first wiring in the first pixel and the third wiring in the third pixel may be placed to exhibit line symmetry with respect to the axis facing the y-axis direction or may have the same arrangement, not arrangement where they are inverted from each other with respect to the y-axis.

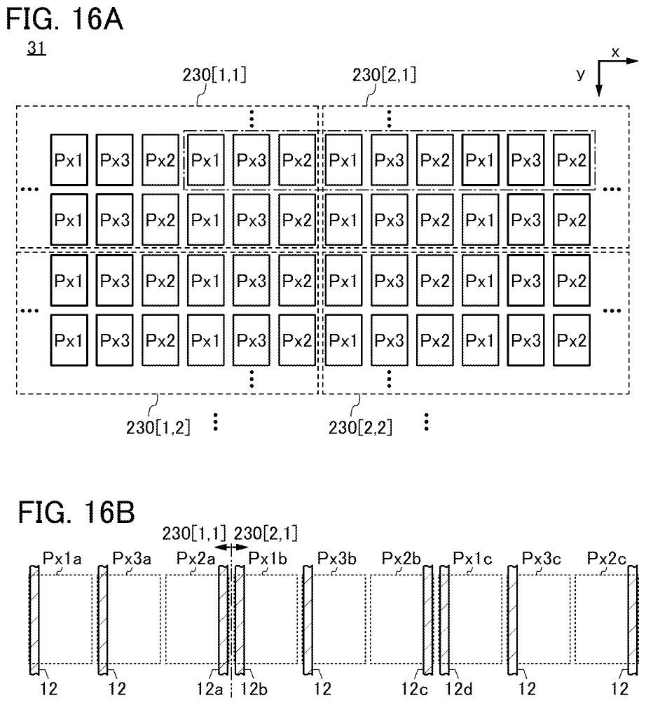

FIG. 16A illustrates an example in which the pixel matrix 230 includes a third type pixel Px (hereinafter sometimes referred to as a pixel Px3) in addition to the pixel Px1 and the pixel Px2. Here, as each of three kinds of pixels Px, the subpixels R, G, B, W, C, M, Y, and the like described above can be employed, for example. Alternatively, as the pixel Px3, among the subpixels R, G, B, W, C, M, Y, and the like, a subpixel other than the subpixels selected for the pixel Px1 and the pixel Px2 may be selected, or a subpixel that is the same as the subpixel for the pixel Px or the pixel Px2 may be selected.

In FIG. 16A, the pixel Px1, the pixel Px3, and the pixel Px2 are sequentially adjacent to each other in the x direction. In addition, the same pixels are arranged in the y direction. FIG. 16A can be expressed as a structure where the pixel Px3 is placed between the pixel Px and the pixel Px2 in the structure illustrated in FIG. 9A, for example. Alternatively, FIG. 16A can be expressed as a structure where a plurality of pixels Px3 arranged in one column along the y direction are placed between a plurality of pixels Px1 arranged in one column along the y direction and a plurality of pixels Px2 arranged in one column along the y direction in the structure illustrated in FIG. 9A, for example.

Alternatively, a structure may be used in which a fourth type pixel Px is placed between the pixel Px1 and the pixel Px2 in addition to the pixel Px3 and the pixel matrix includes four kinds of pixels Px. Alternatively, the kinds of pixels Px included in the pixel matrix may be five or more.

FIG. 16B is an enlarged view of a region surrounded by a dashed-dotted line square in FIG. 16A and illustrates nine pixels arranged according to two adjacent pixel submatrices 230[k,m] (here, the pixel submatrix 230[1,1] and the pixel submatrix 230[2,1]) in the x direction. Here, the pixel Px1, the pixel Px3, the pixel Px2, the pixel Px1, the pixel Px3, the pixel Px2, the pixel Px1, the pixel Px3, and the pixel Px2 sequentially arranged along the x direction are referred to as the pixel Px1a, a pixel Px3a, the pixel Px2a, the pixel Px1b, a pixel Px3b, the pixel Px2b, the pixel Px1c, a pixel Px3c, and the pixel Px2c, respectively. The pixel Px1a, the pixel Px2a, and the pixel Px3a are included in the pixel submatrix 230[1,1], and the pixel Pxb, the pixel Px2b, the pixel Px3b, the pixel Px1c, the pixel Px3c, and the pixel Px2c are included in the pixel submatrix 230[2,1]. Light exposure is separately performed on the pixel submatrix 230[1,1] and the pixel submatrix 230[2,1]. The pixel Px2a and the pixel Px1b are adjacent to each other with a boundary of light exposure regions therebetween.

The pixel Px1, the pixel Px2, and the pixel Px3 each include the wiring 12.

Although FIG. 16B illustrates an example in which the pixel Px3 and the pixel Px2 have symmetrical arrangement with respect to the axis facing the y-axis direction, the pixel Px3 and the pixel Px1 may have symmetrical arrangement with respect to the axis facing the y-axis direction.

For the pixel Px2a and the pixel Px1b adjacent to each other with a boundary of light exposure regions therebetween illustrated in FIG. 16B, the pixel Px2a and the pixel Px1b illustrated in FIG. 9B or the like can be referred to as appropriate. In addition, for the pixel Px2b and the pixel Px1c, the pixel Px2b and the pixel Px1c illustrated in FIG. 9B or the like can be referred to as appropriate.

### [Structure Example 2 of Display Portion]

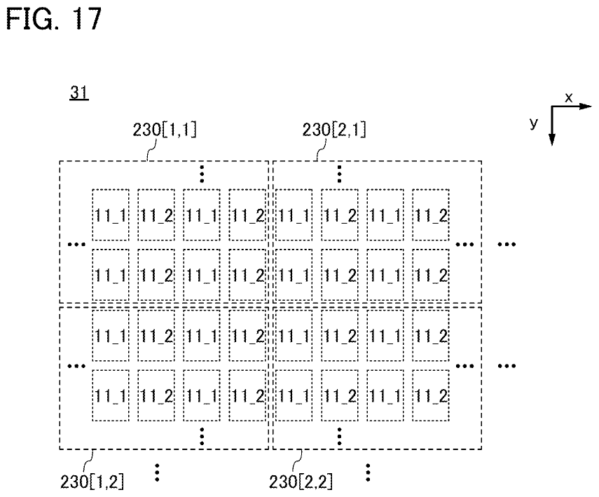

The display portion 31 illustrated in FIG. 17 includes a plurality of pixels 11 arranged in a matrix. The pixel 11 includes a plurality of subpixels. A pixel Px that controls red light, a pixel Px that controls green light, and a pixel Px that controls blue light can be used as the subpixels included in the pixel 11.

Note that FIG. 17 illustrates a structure example in which two kinds of pixels 11 (hereinafter referred to as the pixel 11_1 and the pixel 11_2) are used. The pixel 11_1 and the pixel 11_2 differ from each other in wiring arrangement.

The display portion 31 illustrated in FIG. 17 includes a plurality of pixel submatrices 230[k,m]. A single light exposure region is each of the divided pixel submatrices 230[k,m].

The pixel submatrices 230[k,m] illustrated in FIG. 17 include a plurality of pixels 11_1 and a plurality of pixels 11_2. In addition, in the pixel submatrices 230[k,m], the pixels 11_1 and the pixels 11_2 are alternately arranged along the x direction, and the same pixels are arranged along the y direction.

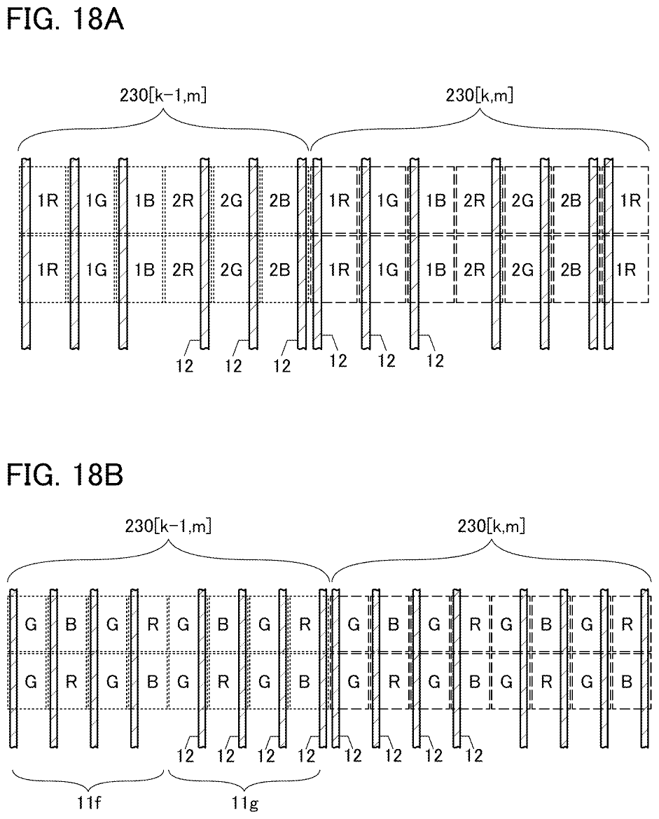

FIG. 18A illustrates an example where the structure illustrated in FIG. 5A is employed for each of the pixels 11_1 and the pixels 11_2 in the structure illustrated in FIG. 17.

In the pixel 11_1, the pixel Px that controls red light, the pixel Px that controls green light, and the pixel Px that controls blue light are denoted by a subpixel 1R, a subpixel 1G, and a subpixel 1B, respectively. In the pixel 11_2, the pixel Px that controls red light, the pixel Px that controls green light, and the pixel Px that controls blue light are denoted by a subpixel 2R, a subpixel 2G, and a subpixel 2B, respectively.

Note that when g equals 3 and f equals 3 in FIG. 15, the pixels 1 if and the pixels 11g are employed as the pixels 11_1 and the pixels 11_2, respectively, three pixels Px1 included in the pixels 11f are the subpixel 1R, the subpixel 1G, and the subpixel 1B, and three pixels Px2 included in the pixels 11g are the subpixel 2R, the subpixel 2G, and the subpixel 2B. Accordingly, a structure illustrated in FIG. 18A can be obtained.

Note that pixels that are adjacent to each other with a boundary of light exposure regions therebetween are not limited to the pixel B and the pixel R. For example, one pixel selected from the pixel R, the pixel G, and the pixel B and one pixel selected from the pixel R, the pixel G, and the pixel B are adjacent to each other.

FIG. 18B illustrates an example where the structure illustrated in FIG. 5F is employed as each of the pixels 11_1 and the pixels 11_2 in the structure illustrated in FIG. 17. In FIG. 18B, the subpixel R included in the pixel 11_2 and the subpixel G included in the pixel 11_1 are adjacent to each other with a boundary of different pixel submatrices therebetween. In addition, the subpixel B included in the pixel 11_2 and the subpixel G included in the pixel 11_1 are adjacent to each other with a boundary of different pixel submatrices therebetween. Note that when g equals 4 and f equals 4 in FIG. 15, a structure where two pixels 1 if arranged along the y direction are used for the pixel 11_1 and the pixel 11_2, and a structure where two pixels 11g arranged along the y direction are used for the pixel 11_1 and the pixel 11_2. Accordingly, a structure illustrated in FIG. 18B can be obtained.

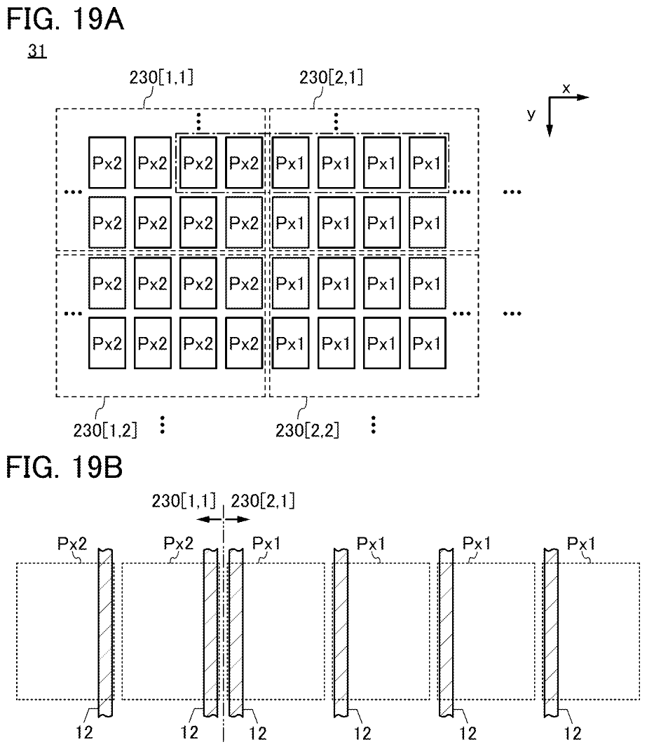

Alternatively, as illustrated in FIG. 19A, the kinds of pixels may be changed depending on the light exposure region for division light exposure. FIG. 19A illustrates an example in which the pixels Px2 are employed for the pixel submatrix 230[1,1] and a pixel submatrix 230[1,2] and the pixels Px1 are employed for the pixel submatrix 230[2,1] and a pixel submatrix 230[2,2]. FIG. 19B is an enlarged view of a region surrounded by a dashed-dotted line square in FIG. 19A.

### [Structure Example 3 of Display Portion]

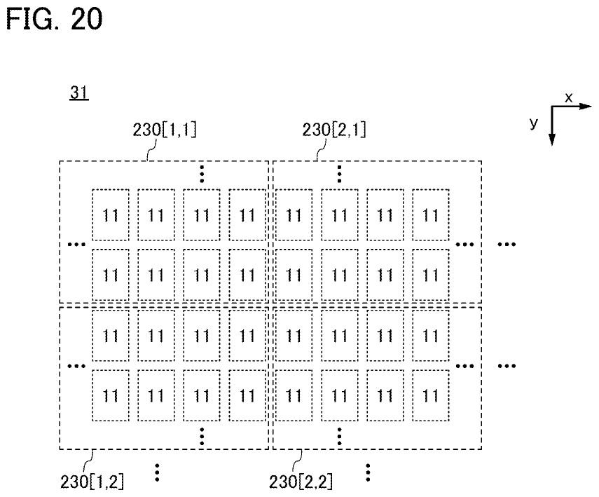

Although FIG. 17 illustrates the example in which the display portion 31 includes two kinds of pixels 11, FIG. 20 illustrates an example in which the display portion 31 includes one kind of pixel 11. In FIG. 20, each pixel submatrix 230[k,m] includes a plurality of pixels 11.

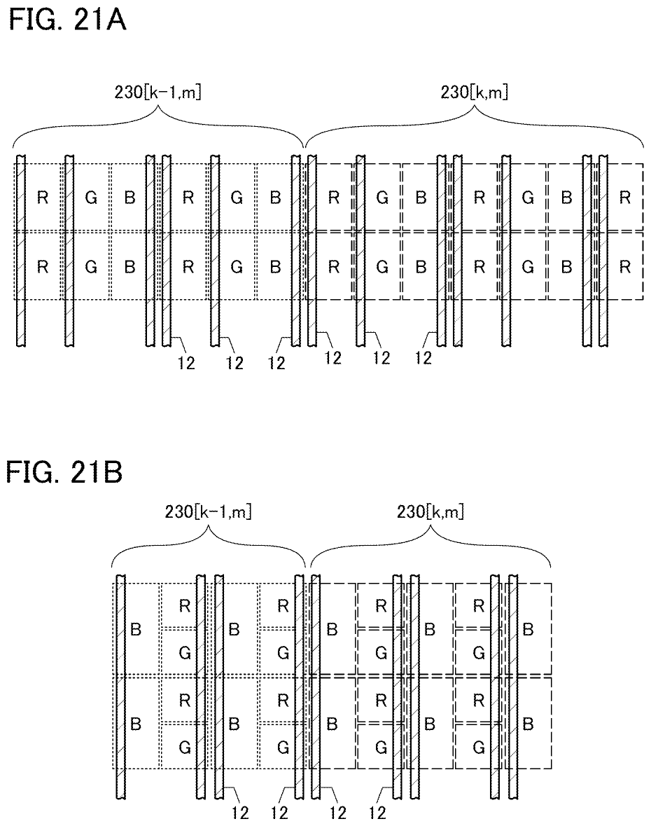

FIG. 21A illustrates an example in which in the structure illustrated in FIG. 20, FIG. 5A is employed for each of the pixels 11. Note that when the subpixel R, the subpixel B, and the subpixel G are employed for the pixel Px1, the pixel Px2, and the pixel Px3, respectively, in FIG. 16B, a structure illustrated in FIG. 21A can also be obtained.

Note that pixels that are adjacent to each other with a boundary of light exposure regions therebetween are not limited to the pixel B and the pixel R. For example, one pixel selected from the pixel R, the pixel G, and the pixel B and one pixel selected from the pixel R, the pixel G, and the pixel B are adjacent to each other.

FIG. 21B illustrates an example in which in the structure illustrated in FIG. 20, FIG. 5C is employed for each of the pixels 11. In FIG. 21B, the subpixel R included in the pixel 11 in a pixel submatrix 230[k−1,m] and the subpixel B included in the pixel 11 in the submatrix 230[k,m] are adjacent to each other with a boundary of the two pixel submatrices therebetween. In addition, the subpixel G included in the pixel 11 in the pixel submatrix 230[k−1,m] and the subpixel B included in the pixel 11 in the submatrix 230[k,m] are adjacent to each other with a boundary of the two pixel submatrices therebetween.

The structure in FIG. 21B can be expressed as a structure where a first row and a second row are alternately arranged in the y direction. In addition, the expression “the subpixels B are included in both the first row and the second row” is used in some cases.

In FIG. 21B, for example, the structure illustrated in FIG. 9B can be used as the structure of the first row, so that the pixels Px1 are the subpixels B and the pixels Px2 are the subpixels R In addition, for example, the structure illustrated in FIG. 9B can be used as the structure of the second row, so that the pixels Px1 are the subpixels B and the pixels Px2 are the subpixels G.

Alternatively, in FIG. 21B, the expression “the subpixels B are included in either one of the first row and the second row” is used in some cases.

The structures described in this embodiment can be used in an appropriate combination with the structures described in the other embodiments and the like.

### Embodiment 2

In this embodiment, display devices according to one embodiment of the present invention will be described.

### [Display Device 400A]

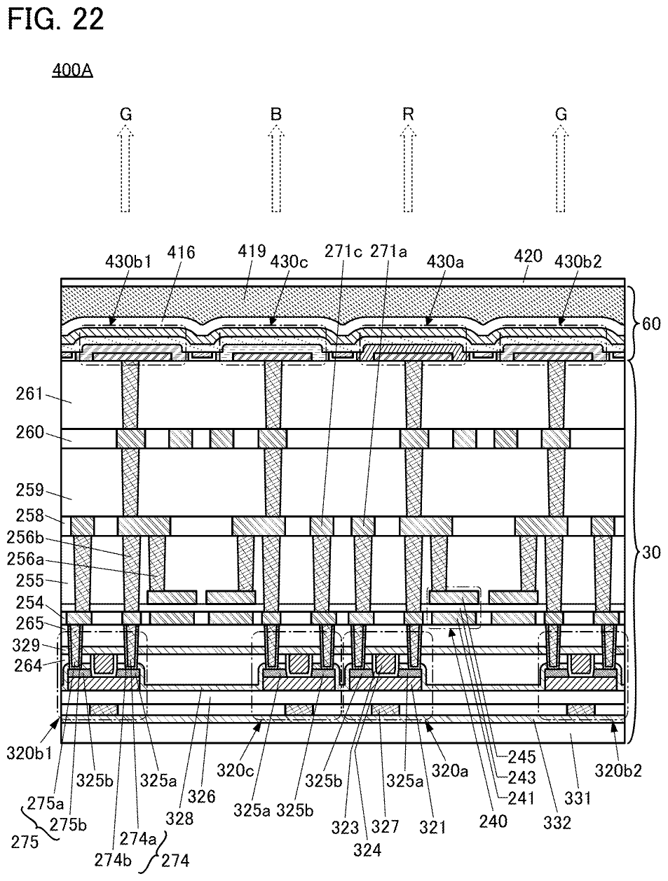

A display device 400A illustrated in FIG. 22 includes a substrate 331, transistors 320 (a transistor 320a, a transistor 320b1, a transistor 320b2, and a transistor 320c), a light-emitting element 430a, a light-emitting element 430b, a light-emitting element 430c, and capacitors 240. Hereinafter, the light-emitting element 430a, the light-emitting element 430b, and the light-emitting element 430c are collectively referred to as a light-emitting element 430 in some cases. Note that FIG. 22 illustrates two light-emitting elements 430b. The two light-emitting elements 430b are denoted by a light-emitting element 430b1 and a light-emitting element 430b2. A structure including the substrate 331, the transistors 320 over the substrate 331, and the capacitors 240 over the transistors can be employed for the layer 30 in FIG. 1A, FIG. 1B, or the like. In addition, a structure including the light-emitting elements 430a, 430b1, 430b2, and 430c can be employed for the layer 60 in FIG. 1A, FIG. 1B, or the like.

FIG. 22 illustrates an example where the light-emitting element 430b1, the light-emitting element 430c, the light-emitting element 430a, and the light-emitting element 430b2 are sequentially arranged as four adjacent light-emitting elements.

The transistor 320 is a transistor in which a metal oxide (also referred to as an oxide semiconductor) is employed in a semiconductor layer where a channel is formed. FIG. 22 illustrates the transistor 320b1, the transistor 320c, the transistor 320a, and the transistor 320b2 that are electrically connected to the light-emitting element 430b1, the light-emitting element 430c, the light-emitting element 430a, and the light-emitting element 430b1 sequentially arranged, respectively, as the transistors 320 included in the display device 400A. For example, a light-emitting element that exhibits red light emission, light-emitting elements that exhibit green light emission, and a light-emitting element that exhibits blue light emission are used as the light-emitting element 430a, the light-emitting element 430b1 and the light-emitting element 430b2, and the light-emitting element 430c, respectively.

The transistor 320 includes a semiconductor layer 321, an insulating layer 323, a conductive layer 324, a pair of conductive layers 325 (hereinafter sometimes referred to as a conductive layer 325a and a conductive layer 325b), an insulating layer 326, and a conductive layer 327.

As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a film of a metal oxide having semiconductor characteristics (also referred to as an oxide semiconductor). A material that can be suitably used for the semiconductor layer 321 will be described in detail later.

The pair of conductive layers 325 is provided on and in contact with the semiconductor layer 321, and functions as a source electrode and a drain electrode.

In addition, an insulating layer 328 is provided to cover top surfaces and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with side surfaces of the insulating layer 264, the insulating layer 328, and the conductive layer 325 and a top surface of the semiconductor layer 321 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are planarized so that they are substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layer 328 and the insulating layer 332 can be used.

A plug 274 that is electrically connected to one of the pair of conductive layers 325 (hereinafter sometimes referred to as the conductive layer 325a) and a plug 275 that is electrically connected to the other of the pair of conductive layers 325 (hereinafter sometimes referred to as the conductive layer 325b) are each provided to be embedded in the insulating layer 265, the insulating layer 329, and the insulating layer 264. Here, the plug 274 preferably includes a conductive layer 274b that is in contact with a top surface of a conductive layer 274a and the conductive layer 274a that covers side surfaces of openings formed in the insulating layer 265, the insulating layer 329, the insulating layer 264, and the insulating layer 328 and part of a top surface of the conductive layer 325. In addition, the plug 275 preferably includes a conductive layer 275b that is in contact with a top surface of a conductive layer 275a and the conductive layer 275a that covers side surfaces of openings formed in the insulating layer 265, the insulating layer 329, the insulating layer 264, and the insulating layer 328 and part of a top surface of the conductive layer 325. At this time, a conductive material in which hydrogen and oxygen are less likely to diffuse is preferably used for the conductive layer 274a and the conductive layer 275a.

In addition, the capacitor 240 is provided over the insulating layer 265.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over an insulating layer 261 and is embedded in an insulating layer 254. The insulating layer 243 is provided to cover the conductive layer 241. The conductive layer 245 is provided in a region overlapped with the conductive layer 241 with the insulating layer 243 therebetween.

An insulating layer 255 is provided to cover the capacitor 240, and plugs such as a plug 256a and a plug 256b are embedded in the insulating layer 255. An insulating layer 258 is provided over the insulating layer 255. An insulating layer 259 is provided over the insulating layer 258. An insulating layer 260 is provided over the insulating layer 259. The insulating layer 261 is provided over the insulating layer 260. The light-emitting elements 430a, 430b, and 430c, and the like are provided over the insulating layer 261. A plurality of conductive layers are embedded in the insulating layer 258 and the insulating layer 260. In addition, a plurality of plugs are embedded in the insulating layer 259 and the insulating layer 261.

The display device 400A may have a structure in which one or more of the insulating layer 259, the plugs embedded in the insulating layer 259, the insulating layer 260, the conductive layers embedded in the insulating layer 260, the insulating layer 261, and the plugs embedded in the insulating layer 261 are not included.

The conductive layer 245 is electrically connected to one of a source and a drain of the transistor 320 through the plug 256a, the conductive layers embedded in the insulating layer 258, the plug 256b, the conductive layer embedded in the insulating layer 254, and the plug 274. The other of the source and the drain of the transistor 320 is electrically connected to the conductive layers embedded in the insulating layer 258 through the plug 275, the conductive layer embedded in the insulating layer 254, and the plugs embedded in the insulating layer 243 and the insulating layer 255.

FIG. 22 illustrates a conductive layer 271c and a conductive layer 271a that are embedded in the insulating layer 258. The conductive layer 325b included in the transistor 320c is electrically connected to the conductive layer 271c. The conductive layer 325b included in the transistor 320a is electrically connected to the conductive layer 271a.

A protective layer 416 is provided over the light-emitting element 430a, the light-emitting element 430b, and the light-emitting element 430c, and a substrate 420 is attached to a top surface of the protective layer 416 with a resin layer 419. The substrate 420 corresponds to the sealing substrate 40 illustrated in FIG. 1A, FIG. 1B, or the like.

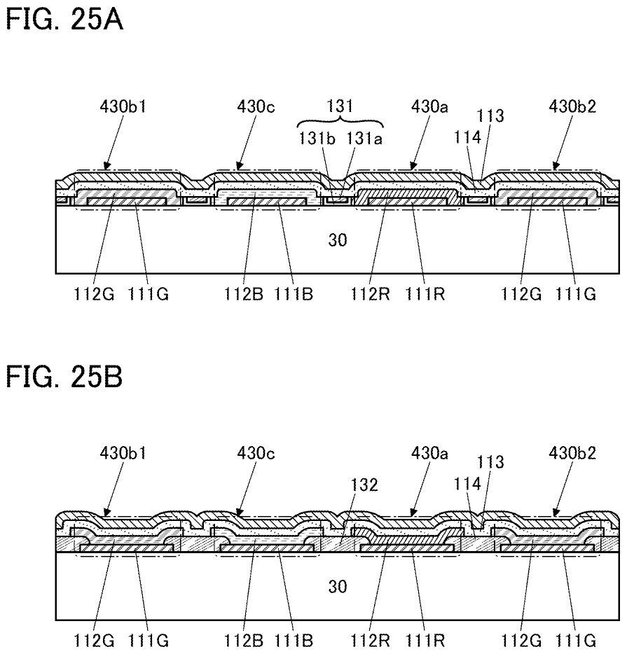

FIG. 25A illustrates structure examples of the light-emitting element 430a, the light-emitting element 430b, and the light-emitting element 430c. In a cross-sectional view illustrated in FIG. 25A, the light-emitting element 430b1, the light-emitting element 430c, the light-emitting element 430a, and the light-emitting element 430b2 are provided over the layer 30. The light-emitting element 430a includes a pixel electrode 111R, an EL layer 112R, and a common electrode 113. The light-emitting elements 430b1 and 430b2 each include a pixel electrode 111G, an EL layer 112G, and the common electrode 113. The light-emitting element 430c includes a pixel electrode 111B, an EL layer 112B, and the common electrode 113.

The light-emitting element 430a, the light-emitting element 430b, and the light-emitting element 430c will be described in detail later.

The pixel electrodes (the pixel electrode 111R, the pixel electrode 111G, and the pixel electrode 111B) of the light-emitting element 430a, the light-emitting element 430b, and the light-emitting element 430c are electrically connected to ones of sources and drains of the transistors 320 through the plug 274, the conductive layer embedded in the insulating layer 254, the plug 256b, the conductive layers embedded in the insulating layer 258, the plugs embedded in the insulating layer 259, the conductive layers embedded in the insulating layer 260, and the plugs embedded in the insulating layer 261.

Here, in the case where the transistor 320 is employed as the transistor 52C illustrated in FIG. 6A and FIG. 6B, for example, the conductive layer 271c has a function of the wiring V0 that is electrically connected to the pixel circuit 51 for driving the light-emitting element 430c, and the conductive layer 271a has a function of the wiring V0 that is electrically connected to the pixel circuit 51 for driving the light-emitting element 430a. The conductive layer 271a and the conductive layer 271c are formed by processing the same conductive film, for example.

In FIG. 22, the transistor 320c and the transistor 320b2 each have a structure of the transistor 320b1 that is inverted horizontally. A pixel circuit including the transistor 320c and a pixel circuit including the transistor 320a in FIG. 22 have substantially bilaterally symmetrical structures. Thus, in FIG. 22, the conductive layer 271c and the conductive layer 271a are placed to be adjacent to each other. In addition, the wiring V0 is a wiring for applying a reference potential, and the same potential is applied to the conductive layer 271c and the conductive layer 271a, for example.

<Formation of Conductive Layer 271c and Conductive Layer 271a>

In the case where light exposure including a pattern for forming the conductive layer 271c and light exposure including a pattern for forming the conductive layer 271a are separately performed, there is a concern that the conductive layer 271c and the conductive layer 271a are short-circuited when the conductive layer 271c and the conductive layer 271a are adjacent to each other or overlapped with each other due to light exposure misalignment. In particular, in the case where the definition of a display portion included in the display device according to one embodiment of the present invention is extremely high, a distance between wirings and the like included in pixels might be extremely short.

When the conductive layer 271c and the conductive layer 271a are used as wirings to which the same potential is applied, even if short circuit occurs between two conductive layers, malfunction of pixel circuits connected to the conductive layers can be inhibited.

A method for manufacturing the display device according to one embodiment of the present invention includes manufacture of a plurality of transistors including the transistor 320b1, the transistor 320c, the transistor 320a, and the transistor 320b2, a step of manufacturing conductive layers including the conductive layer 271c, the conductive layer 271a, and the like over the manufactured plurality of transistors, and a step of manufacturing a plurality of light-emitting elements arranged in a matrix including 430b1, the light-emitting element 430c, the light-emitting element 430a, and the light-emitting element 430b1 over the conductive layers.

An example of a step of forming the conductive layers including the conductive layer 271c and the conductive layer 271a is described.

First, a conductive film that is to be the conductive layer 271c and the conductive layer 271a is deposited over a transistor 20b1, the transistor 320c, the transistor 320a, and the transistor 320b2.

Then, a photo resist is deposited on the conductive film. For the photo resist, a positive type resist material, a negative type resist material, a resist material containing a photosensitive resin, or the like can be used.

Next, light exposure treatment is performed on the photo resist on a first region including a region that is to be the conductive layer 271c, so that patterns that correspond to a plurality of conductive layers including the conductive layer 271c are transferred onto the photo resist.

Then, light exposure treatment is performed on the photo resist on a second region including a region that is to be the conductive layer 271a, so that patterns that correspond to a plurality of conductive layers including the conductive layer 271a are transferred onto the photo resist.

Note that in a plan view, the first region and the second region are regions adjacent to each other. In addition, part of the first region and part of the second region are overlapped with each other in some cases.

Next, development treatment is performed on the photo resist, so that patterns that correspond to the plurality of conductive layers including the conductive layer 271c and the conductive layer 271a are formed on the photo resist.

Here, the conductive layer 271a and the conductive layer 271c are adjacent to each other. Thus, it is preferable not to provide a conductive layer between the conductive layer 271a and the conductive layer 271c. In other words, it is preferable not to form a pattern in a region of the photo resist that is between the conductive layer 271a and the conductive layer 271c.

Then, part of the conductive film is removed using the pattern. Through the above steps, the plurality of conductive layers including the conductive layer 271c and the conductive layer 271a can be formed.

### [Display Device 400B]

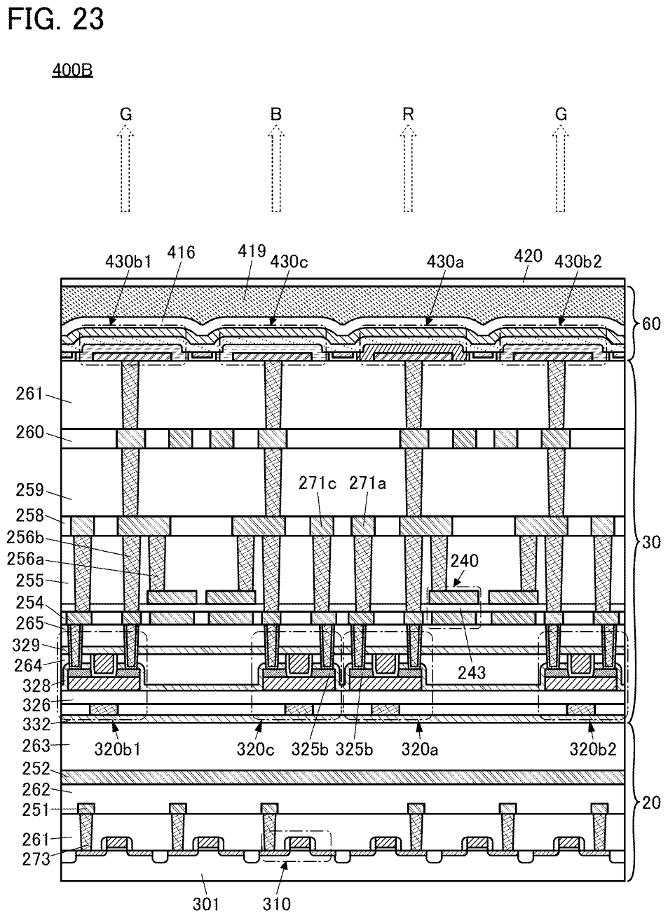

A display device 400B illustrated in FIG. 23 includes the layer 20 including a transistor 310 where a channel is formed in a substrate 301, and the like; the layer 30 including the transistor 320 that is positioned over the layer 20 and contains a metal oxide in a semiconductor layer where a channel is formed, and the like; and the layer 60 that is positioned over the layer 30 and includes the light-emitting element 430a, the light-emitting element 430b, the light-emitting element 430c, and the like. Note that the description of portions similar to those of the display device 400A is omitted in some cases. The layer 20 preferably includes a transistor using a single crystal semiconductor substrate such as a single crystal silicon substrate.

The insulating layer 261 is provided to cover the transistor 310, and a conductive layer 251 is provided over the insulating layer 261. A conductive layer 273 is provided to be embedded in an opening portion of the insulating layer 261. The conductive layer 273 is electrically connected to a source region or a drain region of the transistor 310 and a conductor 251. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistors 320b1, 320c, 320a, and 320b2 are provided over the insulating layer 332. Moreover, the insulating layer 265 is provided to cover the transistors 320b1, 320c, 320a, and 320b2, and the capacitor 240 is provided over the insulating layer 265.

Each of the transistors 320b1, 320c, 320a, and 320b2 can be used as a transistor included in a pixel circuit. In addition, the transistor 310 can be used as a transistor included in a pixel circuit or a transistor included in a driver circuit (a gate line driver circuit or a source line driver circuit) for driving the pixel circuit. Furthermore, the transistor 310 and the transistors 320b1, 320c, 320a, and 320b can also be used as transistors included in a variety of circuits such as an arithmetic circuit or a memory circuit.

In addition, the capacitor 240 and a capacitor using the insulating layer 243 as a dielectric can be used as capacitors included in the pixel circuit.

For the layer 30 and the layer 60, the display device 400A illustrated in FIG. 22 can be referred to.

With such a structure, not only the pixel circuit but also the driver circuit or the like can be formed directly under the light-emitting element; thus, the display device can be downsized as compared to the case where the driver circuit is provided around a display region.

### [Display Device 400C]

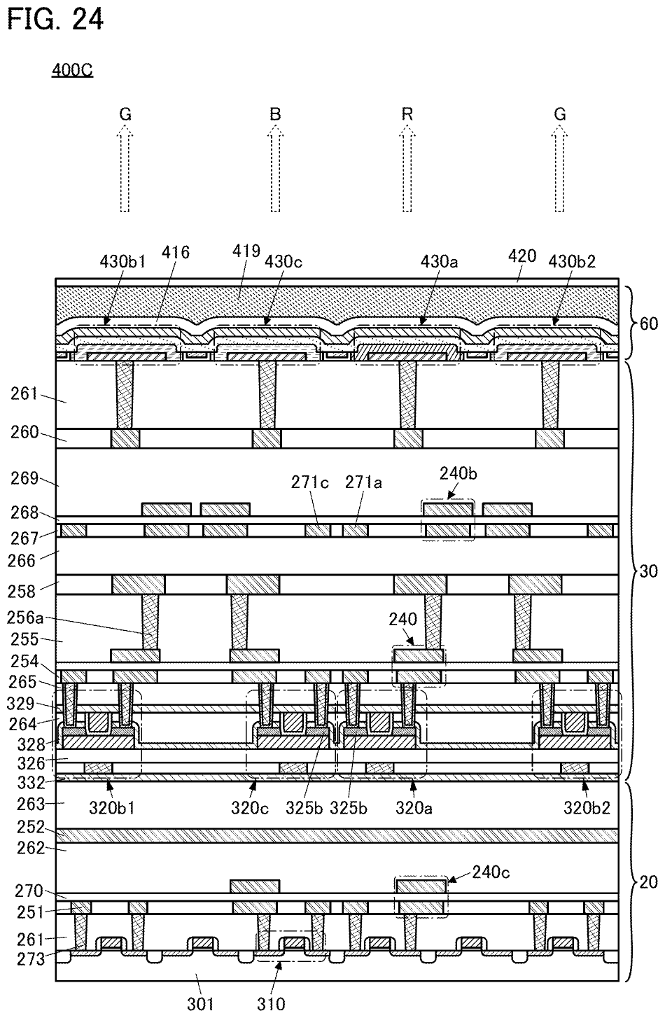

A display device 400C illustrated in FIG. 24 differs from the display device 400B illustrated in FIG. 23 in that capacitors 240c and the like are included between the insulating layer 261 and the conductive layer 252 in the layer 20 and that capacitors 240b and the like are included between the insulating layer 258 and the insulating layer 260 in the layer 30. Note that the description of portions similar to those of the display device 400A or the display device 400B is omitted in some cases.

The display device 400C illustrated in FIG. 24 includes, in the layer 20, the conductive layer 251 over the insulating layer 261, an insulating layer 270 over the conductive layer 251, the insulating layer 262 over the insulating layer 270, and the conductive layer 252 over the insulating layer 262. In addition, over the insulating layer 261, a capacitor using the insulating layer 270 as a dielectric, for example, the capacitor 240c is provided.

The display device 400C illustrated in FIG. 24 includes, in the layer 30, the transistors 320b1, 320c, 320a, and 320b2, the capacitors 240 and 240b, and the conductive layers 271a and 271c.

In FIG. 24, the conductive layers 325a of the transistors 320b1, 320c, 320a, and 320b2 are each provided over the insulating layer 265 and are each electrically connected to a capacitor using the insulating layer 243 as a dielectric, for example, the capacitor 240 or the like. The display device 400C includes the insulating layer 255 over the capacitor using the insulating layer 243 as a dielectric, the insulating layer 258 over the insulating layer 255, an insulating layer 266 over the insulating layer 258, an insulating layer 267 over the insulating layer 266, an insulating layer 268 over the insulating layer 267, an insulating layer 269 over the insulating layer 268, and the insulating layer 260 over the insulating layer 269. In addition, over the insulating layer 266, a capacitor using the insulating layer 268 as a dielectric, for example, the capacitor 240b is provided. Furthermore, the conductive layers 271a and 271c are provided over the insulating layer 266. Although FIG. 24 illustrates an example in which the conductive layers 271a and 271c are formed to be embedded in the insulating layer 267, the conductive layers 271a and 271c may be provided in another insulating layer.

Alternatively, the display device 400C may include a capacitor that uses, as a dielectric, an insulating layer functioning as a gate insulator of a transistor where a channel is formed in the substrate 301.

In addition, the capacitor using the insulating layer 268 as a dielectric, such as the capacitor 240b; the capacitor using the insulating layer 270 as a dielectric, such as the capacitor 240c; and the capacitor that uses, as a dielectric, an insulating layer functioning as a gate insulator of the transistor where a channel is formed in the substrate 301 can be used as capacitors included in a pixel circuit.

At least part of the structure examples, the drawings corresponding thereto, and the like described in this embodiment as an example can be combined with the other structure examples, the other drawings, and the like as appropriate.

### Embodiment 3

In this embodiment, light-emitting elements according to one embodiment of the present invention will be described.

### [Structure Example of Light-Emitting Element]

FIG. 25A illustrates examples of the light-emitting elements included in the display device according to one embodiment of the present invention.

FIG. 25A illustrates a cross-sectional view of a plurality of light-emitting elements provided over the layer 30. In the cross-sectional view illustrated in FIG. 25A, the light-emitting element 430b1, the light-emitting element 430c, the light-emitting element 430a, and the light-emitting element 430b2 are provided over the layer 30. The light-emitting element 430a includes the pixel electrode 111R, the EL layer 112R, and the common electrode 113. The light-emitting elements 430b1 and 430b2 each include the pixel electrode 111G, the EL layer 112G, and the common electrode 113. The light-emitting element 430c includes the pixel electrode 111B, the EL layer 112B, and the common electrode 113. Hereinafter, the pixel electrode 111R, the pixel electrode 111G, and the pixel electrode 111B are collectively referred to as a pixel electrode 111 in some cases.

Each of the pixel electrode 111R, the pixel electrode 111G, and the pixel electrode 111B is electrically connected to a semiconductor element included in the layer 30. In FIG. 22 and FIG. 23, the pixel electrode 111G included in the light-emitting element 430b1 is electrically connected to one of a source and a drain of the transistor 320b1. In addition, the pixel electrode 111B included in the light-emitting element 430c is electrically connected to one of a source and a drain of the transistor 320c. Furthermore, the pixel electrode 111R included in the light-emitting element 430a is electrically connected to one of a source and a drain of the transistor 320a. Moreover, the pixel electrode 111G included in the light-emitting element 430b2 is electrically connected to one of a source and a drain of the transistor 320b2.

The EL layer 112R, the EL layer 112G, and the EL layer 112B are provided over the pixel electrode 111R, the pixel electrode 111G, and the pixel electrode 111B, respectively. The common electrode 113 is provided over the EL layer 112R, the EL layer 112G, and the EL layer 112B (hereinafter collectively referred to as an EL layer 112).

The EL layer 112R contains at least a light-emitting organic compound that emits light with intensity in a red wavelength range. The EL layer 112G contains at least a light-emitting organic compound that emits light with intensity in a green wavelength range. The EL layer 112B contains at least a light-emitting organic compound that emits light with intensity in a blue wavelength range.

The EL layer 112R, the EL layer 112G, and the EL layer 112B each include a layer containing a light-emitting organic compound (a light-emitting layer). The light-emitting layer may contain one or more kinds of compounds (a host material and an assist material) in addition to a light-emitting substance (a guest material). As the host material and the assist material, one or more kinds of substances having a larger energy gap than the light-emitting substance (the guest material) can be selected and used. As the host material and the assist material, compounds that form an exciplex are preferably used in combination. In order to form an exciplex efficiently, it is particularly preferable to combine a compound that easily accepts holes (a hole-transport material) and a compound that easily accepts electrons (an electron-transport material).

Either a low molecular type compound or a high molecular type compound can be used for the light-emitting element, and an inorganic compound (such as a quantum dot material) may be contained in the light-emitting element.

The EL layer 112R, the EL layer 112G, and the EL layer 112B may each include one or more of an electron-injection layer, an electron-transport layer, a hole-injection layer, and a hole-transport layer in addition to the light-emitting layer.

In addition, a common layer 114 may be provided between the EL layer 112 and the common electrode 113. Like the common electrode 113, the common layer 114 is provided across a plurality of light-emitting elements. The common layer 114 is provided to cover the EL layer 112R, the EL layer 112G, and the EL layer 112B. A structure including the common layer 114 can simplify manufacturing steps and thus can reduce manufacturing cost. The common layer 114 and the common electrode 113 can be successively formed without an etching step or the like between formations of the common layer 114 and the common electrode 113. Thus, an interface between the common layer 114 and the common electrode can be a clean surface, and the light-emitting element can have favorable characteristics.

The common layer 114 is preferably in contact with one or more of top surfaces of the EL layer 112R, the EL layer 112G, and the EL layer 112B.

Each of the EL layer 112R, the EL layer 112G, and the EL layer 112B preferably includes at least a light-emitting layer containing a light-emitting material that emits light of one color, for example. In addition, the common layer 114 preferably includes one or more of an electron-injection layer, an electron-transport layer, a hole-injection layer, and a hole-transport layer, for example. In the light-emitting element in which the pixel electrode serves as an anode and the common electrode serves as a cathode, a structure including the electron-injection layer or a structure including the electron-injection layer and the electron-transport layer can be used as the common layer 114.

The pixel electrode 111R, the pixel electrode 111G, and the pixel electrode 111B are provided for the respective light-emitting elements. In addition, the common electrode 113 is provided as a continuous layer shared by the light-emitting elements. A conductive film having a property of transmitting visible light is used for either the respective pixel electrodes or the common electrode 113, and a reflective conductive film is used for the other. When the respective pixel electrodes are light-transmitting electrodes and the common electrode 113 is a reflective electrode, a bottom-emission type display device can be obtained. In contrast, when the respective pixel electrodes are reflective electrodes and the common electrode 113 is a light-transmitting electrode, a top-emission type display device can be obtained. Note that when both the pixel electrodes and the common electrode 113 have a light-transmitting property, a dual-emission type display device can be obtained.

In the case where a conductive film having a property of reflecting visible light is used for the pixel electrode 111, silver, aluminum, titanium, tantalum, molybdenum, platinum, gold, titanium nitride, tantalum nitride, or the like can be used, for example. Alternatively, an alloy can be used for the pixel electrode 111. For example, an alloy containing silver can be used. As the alloy containing silver, an alloy containing silver, palladium, and copper can be used, for example. Alternatively, an alloy containing aluminum can be used, for example. Alternatively, a stack of two or more layers of these materials may be used.

Alternatively, over the conductive film having a property of reflecting visible light, a conductive film having a property of transmitting visible light can be used for the pixel electrode 111. A conductive oxide such as indium oxide, indium tin oxide, indium zinc oxide, zinc oxide, zinc oxide containing gallium, indium tin oxide containing silicon, or indium zinc oxide containing silicon can be used as a conductive material having a property of transmitting visible light. Alternatively, an oxide of a conductive material having a property of reflecting visible light may be used, and the oxide may be formed by oxidation of a surface of the conductive material having a property of reflecting visible light. Specifically, for example, titanium oxide may be used. Titanium oxide may be formed by oxidation of a surface of titanium, for example.

Providing an oxide on a surface of the pixel electrode 111 can inhibit oxidation reaction or the like with the pixel electrode 111 at the time of forming the EL layer 112.

Alternatively, when a conductive film having a property of transmitting visible light is stacked and provided over a conductive film having a property of reflecting visible light for the pixel electrode 111, the conductive film having a property of transmitting visible light can function as an optical adjustment layer.

When the pixel electrode 111 includes an optical adjustment layer, an optical path length can be adjusted. The optical path length of each light-emitting element corresponds to, for example, the sum of the thickness of the optical adjustment layer and the thickness of layers provided below a film containing a light-emitting compound in the EL layer 112.

The optical path lengths of the light-emitting elements are set different from each other using a microcavity structure, so that light of a specific wavelength can be intensified. Thus, a display device with increased color purity can be achieved.

For example, the thickness of the EL layer 112 is set different among the light-emitting elements, so that a microcavity structure can be achieved. For example, the EL layer 112R of the light-emitting element 430a emitting light whose wavelength is the longest can be made to have the largest thickness, and the EL layer 112B of the light-emitting element 430c emitting light whose wavelength is the shortest can be made to have the smallest thickness. Note that without limitation to this, the thickness of each EL layer can be adjusted in consideration of the wavelength of light emitted from each light-emitting element, the optical characteristics of the layer included in the light-emitting element, the electrical characteristics of the light-emitting element, and the like.

For simplification, FIG. 25A and the like do not illustrate that the thickness of the EL layer 112 is set to be clearly different among the light-emitting elements; however, as described above, in order to adjust the optical path length, it is preferable that the thickness of the EL layer 112 in each light-emitting element be adjusted as appropriate and that light with a wavelength corresponding to each light-emitting element be intensified.

An insulating layer is preferably provided between adjacent light-emitting elements 430.

FIG. 25A illustrates an example in which insulating layers 131 are provided between the pixel electrodes 111 included in the light-emitting elements 430 and between the EL layers 112. In addition, the common electrode 113 is provided over the insulating layer 131.

The insulating layer 131 includes an insulating layer 131a and an insulating layer 131b. The insulating layer 131b is provided to be in contact with side surfaces of each of the pixel electrodes 111 and side surfaces of the EL layers 112 included in the light-emitting elements 430. Furthermore, the insulating layer 131a is provided on and in contact with the insulating layer 131b to fill a depression portion of the insulating layer 131b in a cross-sectional view.

When the insulating layer 131 is provided between the light-emitting elements of different colors, the EL layer 112R, the EL layer 112G, and the EL layer 112G can be inhibited from being in contact with each other. This can suitably prevent unintentional light emission due to current flowing through two adjacent EL layers. As a result, contrast can be increased, so that a display device with high display quality can be achieved.

The insulating layer 131b can be an insulating layer containing an inorganic material. As the insulating layer 131b, a single layer or a stacked layer of aluminum oxide, magnesium oxide, hafnium oxide, gallium oxide, indium gallium zinc oxide, silicon oxide, silicon oxynitride, silicon nitride, silicon nitride oxide, or the like can be used. In particular, aluminum oxide is preferable because it has high etching selectivity with respect to the EL layer 112 and has a function of protecting the EL layer 112 in forming the insulating layer 131b that is to be described later. In particular, with the use of an inorganic insulating material such as aluminum oxide, hafnium oxide, or silicon oxide formed by an ALD method for the insulating layer 131b, the insulating layer 131b can be a film with few pinholes and can have an excellent function of protecting the EL layer 112.

Note that in this specification, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 131b, a sputtering method, a chemical vapor deposition (CVD) method, a molecular beam epitaxy (MBE) method, a pulsed laser deposition (PLD) method, an atomic layer deposition (ALD) method, or the like can be used. An ALD method achieving favorable coverage can be suitably used for forming the insulating layer 131b.

The insulating layer 131a provided over the insulating layer 131b has a function of planarizing the depression portion of the insulating layer 131b that is formed between the adjacent light-emitting elements. In other words, the insulating layer 131a has an effect of improving the planarity of the formation surface of the common electrode 113. An insulating layer containing an organic material can be suitably used for the insulating layer 131a. For the insulating layer 131a, an acrylic resin, a polyimide resin, an epoxy resin, a polyamide resin, a polyimide-amide resin, a siloxane resin, a benzocyclobutene-based resin, a phenol resin, a precursor of these resins, or the like can be employed, for example. Alternatively, a photosensitive resin can be used for the insulating layer 131a. As the photosensitive resin, a positive photosensitive material or a negative photosensitive material can be used.

When the insulating layer 131a is formed using a photosensitive resin, the insulating layer 131a can be manufactured only by light exposure and development steps; therefore, effects of dry etching, wet etching, or the like at the time of forming the insulating layer 131a on the surface of the EL layer 112 can be reduced.

Alternatively, as illustrated in FIG. 25B, a structure may be provided in which an insulating layer provided between adjacent light-emitting elements 430 is provided over the pixel electrode 111.

FIG. 25B illustrates an example in which insulating layers 132 are provided between the pixel electrodes 111 included in the light-emitting elements 430 and over some of the pixel electrodes 111.

For the insulating layer 132, a material that can be used for the insulating layer 131a can be referred to.

Top surfaces of the insulating layers 132 illustrated in FIG. 25B each have a region in contact with a bottom surface of the EL layer 112 in some cases. In addition, some of the top surfaces of the insulating layers 132 have a region in contact with the common layer 114 between the EL layers 112 included in the light-emitting elements in some cases. Alternatively, in the case where the light-emitting elements 430 do not include the common layer 114, some of the top surfaces of the insulating layers 132 have a region in contact with the common electrode 113 between the EL layers 112 included in the light-emitting elements in some cases.

At least part of structure examples, drawings corresponding thereto, and the like described in this embodiment can be combined with the other structure examples, the other drawings corresponding thereto, and the like as appropriate.

### Embodiment 4

In this embodiment, light-emitting elements (also referred to as light-emitting devices) that can be used for a display device that is one embodiment of the present invention will be described.

### <Structure Example of Light-Emitting Device>

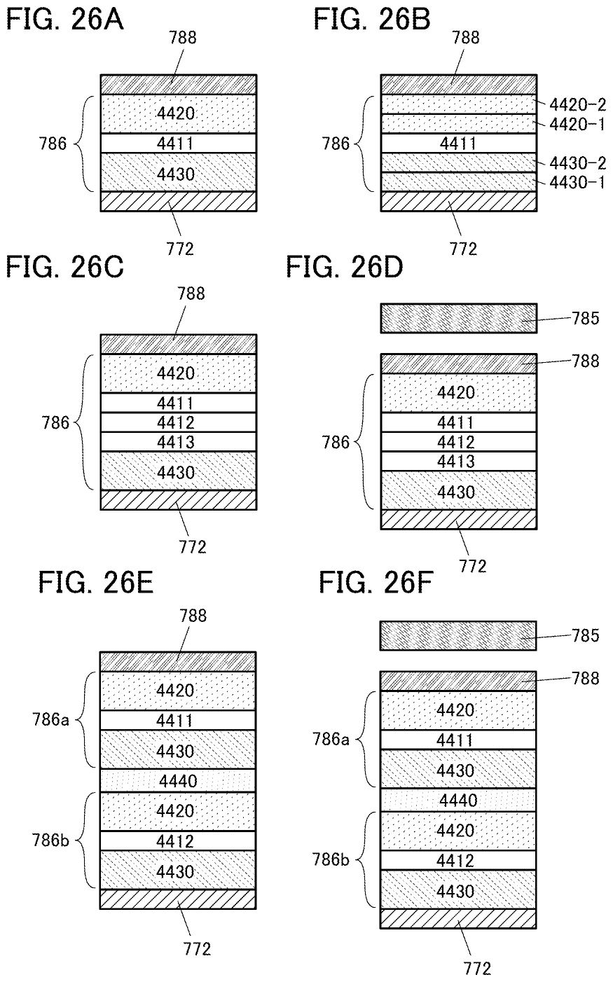

As illustrated in FIG. 26A, a light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

A structure including the layer 4420, the light-emitting layer 4411, and the layer 4430, which is provided between a pair of electrodes, can function as a single light-emitting unit, and the structure in FIG. 26A is referred to as a single structure in this specification.

In addition, FIG. 26B illustrates a modification example of the EL layer 786 included in the light-emitting device illustrated in FIG. 26A. Specifically, the light-emitting device illustrated in FIG. 26B includes a layer 4430-1 over the lower electrode 772, a layer 4430-2 over the layer 4430-1, the light-emitting layer 4411 over the layer 4430-2, a layer 4420-1 over the light-emitting layer 4411, a layer 4420-2 over the layer 4420-1, and the upper electrode 788 over the layer 4420-2. For example, when the lower electrode 772 is an anode and the upper electrode 788 is a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the lower electrode 772 is a cathode and the upper electrode 788 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of recombination of carriers in the light-emitting layer 4411 can be increased.

Note that a structure in which a plurality of light-emitting layers (light-emitting layers 4411, 4412, and 4413) are provided between the layer 4420 and the layer 4430 as illustrated in FIG. 26C or FIG. 26D is a variation of the single structure.

A structure in which a plurality of light-emitting units (an EL layer 786a and an EL layer 786b) are connected in series with an intermediate layer (a charge-generation layer) 4440 therebetween as illustrated in FIG. 26E or FIG. 26F is referred to as a tandem structure in this specification. Note that in this specification and the like, the structure illustrated in FIG. 26E or FIG. 26F is referred to as a tandem structure; however, without being limited to this, a tandem structure may be referred to as a stack structure, for example. Note that the tandem structure enables a light-emitting device to emit light at high luminance.

In FIG. 26C, a light-emitting material that emits the same light may be used for the light-emitting layer 4411, the light-emitting layer 4412, and the light-emitting layer 4413.

Alternatively, different light-emitting materials may be used for the light-emitting layer 4411, the light-emitting layer 4412, and the light-emitting layer 4413. White light emission can be obtained when light emitted from the light-emitting layer 4411, light emitted from the light-emitting layer 4412, and light emitted from the light-emitting layer 4413 have a relationship of complementary colors. FIG. 26D illustrates an example in which a coloring layer 785 functioning as a color filter is provided. When white light passes through a color filter, light of a desired color can be obtained.

In addition, in FIG. 26E, the same light-emitting material may be used for the light-emitting layer 4411 and the light-emitting layer 4412. Alternatively, light-emitting materials that emit different light may be used for the light-emitting layer 4411 and the light-emitting layer 4412. White light emission can be obtained when light emitted from the light-emitting layer 4411 and light emitted from the light-emitting layer 4412 have a relationship of complementary colors. FIG. 26F illustrates an example in which the coloring layer 785 is further provided.

Note that also in FIG. 26C, FIG. 26D, FIG. 26E, and FIG. 26F, the layer 4420 and the layer 4430 may each have a stacked-layer structure of two or more layers as illustrated in FIG. 26B.

A structure in which light emission colors (here, blue (B), green (G), and red (R)) are separately formed for the light-emitting devices is referred to as an SBS (Side By Side) structure in some cases.

The emission color of the light-emitting devices can be red, green, blue, cyan, magenta, yellow, white, or the like depending on materials that constitute the EL layer 786. Furthermore, color purity can be further increased when the light-emitting device has a microcavity structure.

In the case where the light-emitting device emits white light, the light-emitting layer preferably contains two or more kinds of light-emitting substances. To obtain white light emission, two or more light-emitting substances are selected so that their emission colors have a relationship of complementary colors. For example, when the emission color of a first light-emitting layer and the emission color of a second light-emitting layer have a relationship of complementary colors, it is possible to obtain the light-emitting device that emits white light as a whole. The same applies to a light-emitting device including three or more light-emitting layers.

The light-emitting layer preferably contains two or more light-emitting substances that emit red (R) light, green (G) light, blue (B) light, yellow (Y) light, orange (O) light, and the like. Alternatively, the light-emitting layer preferably contains two or more light-emitting substances that emit light containing spectral components of two or more colors out of R, G, and B.

Here, a specific structure example of the light-emitting device is described.

The light-emitting device includes at least the light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like.

Either a low molecular type compound or a high molecular type compound can be used for the light-emitting device, and an inorganic compound may also be contained. Each of the layers included in the light-emitting device can be formed by an evaporation method (including a vacuum evaporation method), a transfer method, a printing method, an inkjet method, a coating method, or the like.

For example, the light-emitting device can include one or more of a hole-injection layer, a hole-transport layer, a hole-blocking layer, an electron-blocking layer, an electron-transport layer, and an electron-injection layer.

The hole-injection layer is a layer injecting holes from an anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 10⁻⁶ cm²/Vs is preferable. Note that other substances can also be used as long as they have a property of transporting more holes than electrons. As the hole-transport material, a material with a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from a cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate.

Alternatively, an electron-transport material may be used for the electron-injection layer. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

The light-emitting layer is a layer containing a light-emitting substance. The light-emitting layer can include one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, a quantum dot material, and the like.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, a naphthalene derivative, and the like.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; a rare earth metal complex; and the like.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, the high efficiency, low-voltage driving, and long lifetime of the light-emitting device can be achieved at the same time.

This embodiment can be implemented in combination with the other embodiments as appropriate.

### Embodiment 5

In this embodiment, a metal oxide (also referred to as an oxide semiconductor) that can be used in the OS transistor described in the above embodiment is described.

A metal oxide preferably contains at least indium or zinc. In particular, indium and zinc are preferably contained. In addition, in addition to these, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

In addition, the metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including completely amorphous), CAAC (c-axis-aligned crystalline), nc (nanocrystalline), CAC (cloud-aligned composite), single-crystal, and polycrystalline (polycrystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The bilaterally asymmetrical peak of the XRD spectrum clearly shows the existence of crystal in the film or the substrate. In other words, the crystal structure of the film or the substrate cannot be regarded as an amorphous state unless it has a bilaterally symmetrical peak in the XRD spectrum.

In addition, the crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), an amorphous oxide semiconductor, and the like.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. In addition, the crystal region refers to a region having periodic atomic arrangement. Note that when atomic arrangement is regarded as lattice arrangement, the crystal region also refers to a region with uniform lattice arrangement. Furthermore, the CAAC-OS has a region where a plurality of crystal regions are connected in an a-b plane direction, and the region has distortion in some cases. Note that distortion refers to a portion where the direction of lattice arrangement changes between a region with uniform lattice arrangement and another region with uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. Alternatively, in the case where the crystal region is formed of a large number of fine crystals, the size of the crystal region is sometimes approximately several tens of nanometers.

In addition, in an In-M-Zn oxide (the element M is one or more kinds selected from aluminum, gallium, yttrium, tin, titanium, and the like), the CAAC-OS tends to have a layer-shaped crystal structure (also referred to as a layer-shaped structure) in which a layer containing indium (In) and oxygen (hereinafter an In layer) and a layer containing the element M, zinc (Zn), and oxygen (hereinafter an (M,Zn) layer) are stacked. Note that indium and the element M can be replaced with each other. Therefore, indium is sometimes contained in the (M,Zn) layer. Furthermore, the element M is sometimes contained in the In layer. Note that Zn is sometimes contained in the In layer. Such a layer-shaped structure is observed as a lattice image in a high-resolution TEM (Transmission Electron Microscope) image, for example.

When the CAAC-OS film is subjected to structural analysis by out-of-plane XRD measurement with an XRD device using θ/2θ scanning, for example, a peak indicating c-axis alignment is detected at 2θ of 31° or around 31°. Note that the position of the peak indicating c-axis alignment (the value of 2θ) might fluctuate depending on the kind, composition, or the like of the metal element contained in the CAAC-OS.

In addition, for example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetrical center.

When the crystal region is observed from the particular direction, lattice arrangement in the crystal region is basically hexagonal lattice arrangement; however, a unit lattice is not always a regular hexagon and is a non-regular hexagon in some cases. In addition, pentagonal lattice arrangement, heptagonal lattice arrangement, and the like are included in the distortion in some cases. Note that a clear grain boundary cannot be observed even in the vicinity of the distortion in the CAAC-OS. That is, it is found that formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, or the like.

Note that a crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, it can be said that a reduction in electron mobility due to the grain boundary is unlikely to occur. In addition, entry of impurities, formation of defects, or the like might decrease the crystallinity of an oxide semiconductor. his means that the CAAC-OS can also be referred to as an oxide semiconductor having small amounts of impurities or defects (oxygen vacancies or the like). Therefore, physical properties of an oxide semiconductor including the CAAC-OS become stable. Accordingly, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region greater than or equal to 1 nm and less than or equal to 10 nm, in particular, a region greater than or equal to 1 nm and less than or equal to 3 nm) has periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. In addition, there is no regularity of crystal orientation between different nanocrystals in the nc-OS. Hence, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD device using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are obtained in the observed electron diffraction pattern when the nc-OS film is subjected to electron diffraction (also referred to as nanobeam electron diffraction) using an electron beam with a probe diameter close to or smaller than the size of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of a CAC-OS film. Moreover, the second region has [Ga] higher than that in the composition of the CAC-OS film. Alternatively, for example, the first region has higher [In] and lower [Ga] than the second region. Moreover, the second region has higher [Ga] and lower [In] than the first region.

Specifically, the first region includes indium oxide, indium zinc oxide, or the like as its main component. In addition, the second region includes gallium oxide, gallium zinc oxide, or the like as its main component. That is, the first region can be referred to as a region containing In as its main component. Furthermore, the second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated, for example. Furthermore, in the case where the CAC-OS is formed by a sputtering method, any one or more selected from an inert gas (typically, argon), an oxygen gas, and a nitrogen gas is used as a deposition gas. Moreover, the ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

In contrast, the second region has a higher insulating property than the first region. In other words, when the second regions are distributed in a metal oxide, leakage current can be inhibited.

In the case where the CAC-OS is used for a transistor, a switching function (On/Off function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

In addition, a transistor using the CAC-OS has high reliability. Thus, the CAC-OS is most suitable for a variety of semiconductor devices such as display devices.

Oxide semiconductors have various structures and each have different properties. Two or more kinds among the amorphous oxide semiconductor, the polycrystalline oxide semiconductor, the a-like OS, the CAC-OS, the nc-OS, and the CAAC-OS may be included in an oxide semiconductor according to one embodiment of the present invention.

### <Transistor Including Oxide Semiconductor>

Next, the case where the oxide semiconductor is used for a transistor is described.

When the oxide semiconductor is used for a transistor, a transistor with high field-effect mobility can be achieved. In addition, a highly reliable transistor can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor film has a low density of defect states and accordingly has a low density of trap states in some cases.

In addition, electric charge captured by the trap states in an oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the concentration in the oxide semiconductor is effective. In addition, in order to reduce the impurity concentration in the oxide semiconductor, the impurity concentration in a film that is adjacent to the oxide semiconductor is also preferably reduced. Examples of impurities include hydrogen, nitrogen, an alkali metal, an alkaline earth metal, iron, nickel, silicon, and the like.

### <Impurities>

Here, the influence of each impurity in the oxide semiconductor is described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

In addition, when the oxide semiconductor contains an alkali metal or an alkaline earth metal, defect states are formed and carriers are generated in some cases. Accordingly, a transistor using an oxide semiconductor that contains an alkali metal or an alkaline earth metal tends to have normally-on characteristics. Thus, the concentration of an alkali metal or an alkaline earth metal in the oxide semiconductor that is obtained by SIMS is lower than or equal to 1×10¹⁸ atoms/cm³, preferably lower than or equal to 2×10¹⁶ atoms/cm³.

In addition, an oxide semiconductor containing nitrogen easily becomes n-type by generation of electrons serving as carriers and an increase in carrier concentration. Thus, a transistor using an oxide semiconductor that contains nitrogen as the semiconductor tends to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor that is obtained by SIMS is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

In addition, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, some hydrogen is bonded to oxygen bonded to a metal atom and generates an electron serving as a carrier. Thus, a transistor using an oxide semiconductor that contains hydrogen tends to have normally-on characteristics. For this reason, hydrogen in the oxide semiconductor is preferably reduced as much as possible. Specifically, the hydrogen concentration in the oxide semiconductor that is obtained by SIMS is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

At least part of this embodiment can be implemented in combination with the other embodiments described in this specification as appropriate.

### Embodiment 6

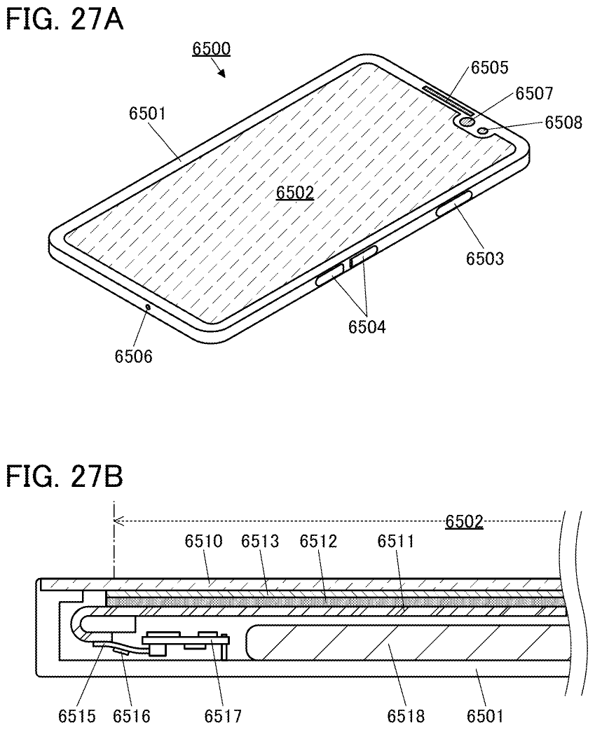

In this embodiment, electronic devices according to embodiments of the present invention are described using FIG. 27 to FIG. 30.

The electronic devices in this embodiment each include the display device according to one embodiment of the present invention. The display device according to one embodiment of the present invention can be easily increased in definition, resolution, and size. Thus, the display device according to one embodiment of the present invention can be used for display portions of a variety of electronic devices.

In addition, the display device according to one embodiment of the present invention can be manufactured at low cost, which leads to a reduction in manufacturing cost of an electronic device.

Examples of the electronic devices include a digital camera, a digital video camera, a digital photo frame, a cellular phone, a portable game machine, a portable information terminal, and an audio reproducing device, in addition to electronic devices provided with comparatively large screens, such as a television device, a desktop or laptop personal computer, a monitor for a computer or the like, digital signage, and a large game machine such as a pachinko machine.

In particular, the display device according to one embodiment of the present invention can have higher definition, and thus can be suitably used for an electronic device having a comparatively small display portion. Examples of such an electronic device include a watch-type or bracelet-type information terminal device (a wearable device); a wearable device that can be worn on a head, such as a device for VR such as a head-mounted display or a glasses-type device for AR; and the like. Examples of wearable devices include a device for SR and a device for MR.

In addition, in the display device according to one embodiment of the present invention, connection of a plurality of light exposure regions can increase the area of a display portion; thus, both high definition and a wide area of the display portion can be achieved. Accordingly, in a watch-type or bracelet-type information terminal device (a wearable device), for example, the amount of information such as an image and a character to be displayed on the display portion can be increased, which is suitable. In addition, the size of a character to be displayed on the display portion can be increased, which is suitable. Furthermore, in a wearable device that can be worn on a head, such as a device for VR, a device for AR, a device for MR, or a device for SR, the level of immersion, realistic sensation, and sense of depth can be further increased.

The resolution of the display device according to one embodiment of the present invention is preferably as high as HD (pixel count: 1280×720), FHD (pixel count: 1920×1080), WQHD (pixel count: 2560×1440), WQXGA (pixel count: 2560×1600), 4K2K (pixel count: 3840×2160), or 8K4K (pixel count: 7680×4320). In particular, the resolution of 4K2K, 8K4K, or higher is preferable. In addition, the pixel density (definition) of the display device according to one embodiment of the present invention is preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, or yet further preferably higher than or equal to 7000 ppi. With the use of such a display device with high resolution or high definition, an electronic device for personal use such as portable use or home use can have higher realistic sensation, sense of depth, and the like.

The electronic device in this embodiment can be incorporated along a curved surface of an inside wall or an outside wall of a house or a building or an interior or an exterior of a motor vehicle.

The electronic device in this embodiment may include an antenna. With the antenna receiving a signal, the electronic device can display an image, information, and the like on a display portion. In addition, in the case where the electronic device includes an antenna and a secondary battery, the antenna may be used for contactless power transmission.

The electronic device in this embodiment may include a sensor (a sensor having a function of measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a storage medium.

An electronic device 6500 illustrated in FIG. 27A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device according to one embodiment of the present invention can be employed for the display portion 6502.

FIG. 27B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display (a flexible display device) according to one embodiment of the present invention can be employed for the display panel 6511. Thus, an extremely lightweight electronic device can be achieved. In addition, since the display panel 6511 is extremely thin, the battery 6518 with high capacity can be mounted with the thickness of the electronic device controlled. Moreover, part of the display panel 6511 is folded back so that a connection portion with the FPC 6515 is provided on the back side of a pixel portion, so that an electronic device with a narrow bezel can be achieved.

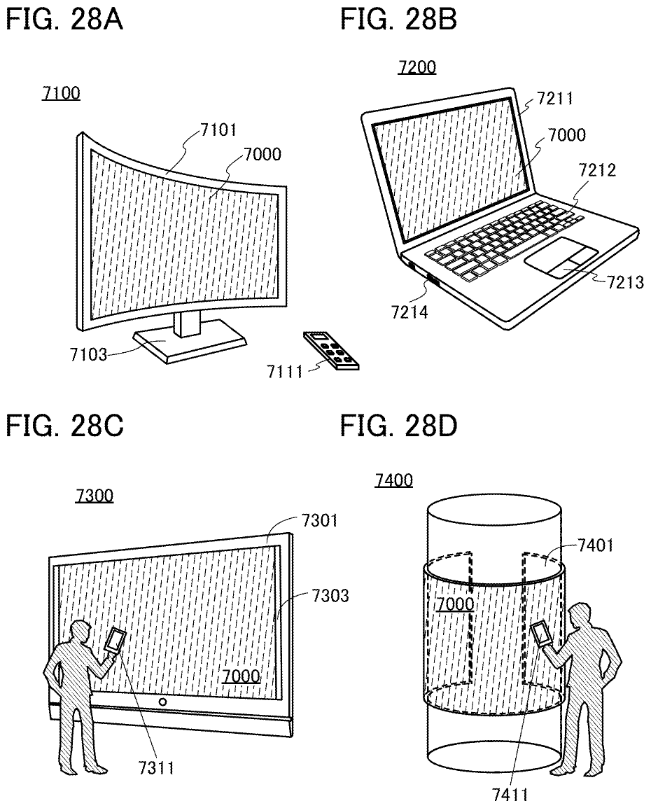

FIG. 28A illustrates an example of a television device. In a television device 7100, a display portion 7000 is incorporated in a housing 7101. Here, a structure in which the housing 7101 is supported by a stand 7103 is illustrated.

The display device according to one embodiment of the present invention can be employed for the display portion 7000.

Operations of the television device 7100 illustrated in FIG. 28A can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and sound volume can be operated and video displayed on the display portion 7000 can be operated.

Note that the television device 7100 has a structure in which a receiver, a modem, and the like are provided. A general television broadcast can be received with the receiver. In addition, when the television device is connected to a communication network with or without wires via the modem, one-way (from a transmitter to a receiver) or two-way (between a transmitter and a receiver or between receivers, for example) data communication can be performed.

FIG. 28B illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device according to one embodiment of the present invention can be employed for the display portion 7000.

FIG. 28C and FIG. 28D illustrate examples of digital signage.

Digital signage 7300 illustrated in FIG. 28C includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 28D is digital signage 7400 attached to a cylindrical pillar 7401. The digital signage 7400 includes the display portion 7000 provided along a curved surface of the pillar 7401.

The display device according to one embodiment of the present invention can be employed for the display portion 7000 illustrated in each of FIG. 28C and FIG. 28D.

The larger display portion 7000 can increase the amount of information that can be provided at a time. In addition, the larger display portion 7000 attracts more attention, so that advertising effects can be increased, for example.

The use of a touch panel in the display portion 7000 is preferable because in addition to display of an image or a moving image on the display portion 7000, an intuitive operation by a user is possible. Moreover, in the case where the display device according to one embodiment of the present invention is used for providing information such as route information or traffic information, usability can be increased by an intuitive operation.

In addition, as illustrated in FIG. 28C and FIG. 28D, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

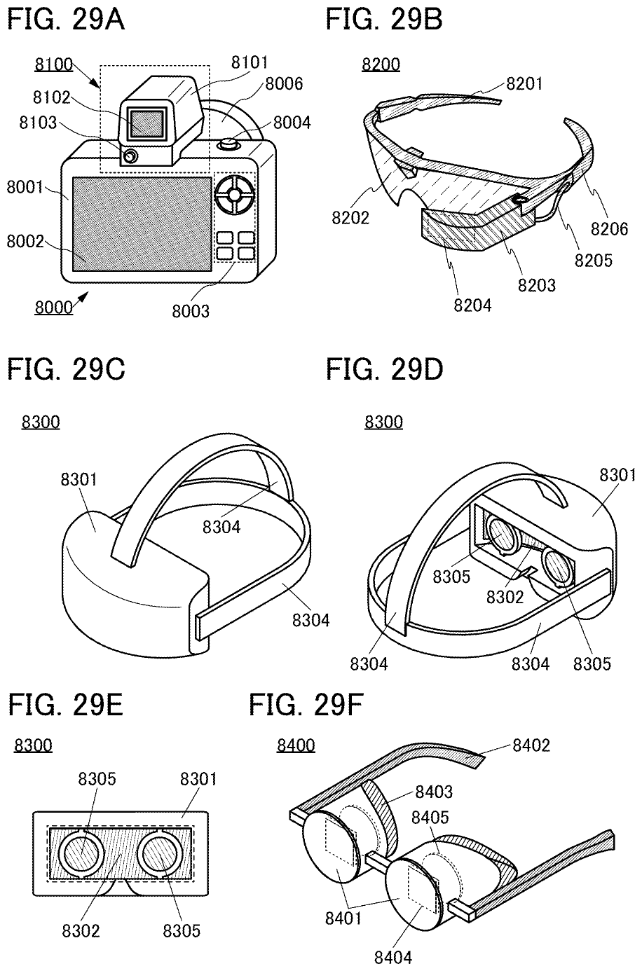

FIG. 29A is a diagram illustrating the appearance of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000. Note that the lens 8006 and the housing may be integrated with each other in the camera 8000.

The camera 8000 can take images by the press of the shutter button 8004 or touch on the display portion 8002 serving as a touch panel.

The housing 8001 includes a mount including an electrode, so that, in addition to the finder 8100, a stroboscope or the like can be connected to the housing.

The finder 8100 includes a housing 8101, a display portion 8102, a button 8103, and the like.

The housing 8101 is attached to the camera 8000 by a mount for engagement with the mount of the camera 8000. The finder 8100 can display video and the like received from the camera 8000 on the display portion 8102.

The button 8103 has a function of a power button or the like.

The display device according to one embodiment of the present invention can be employed for the display portion 8002 of the camera 8000 and the display portion 8102 of the finder 8100. Note that a finder may be incorporated in the camera 8000.

FIG. 29B is a diagram illustrating the appearance of a head-mounted display 8200.

The head-mounted display 8200 includes a wearing portion 8201, a lens 8202, a main body 8203, a display portion 8204, a cable 8205, and the like. In addition, a battery 8206 is incorporated in the wearing portion 8201.

The cable 8205 supplies power from the battery 8206 to the main body 8203. The main body 8203 includes a wireless receiver or the like and can display received video information on the display portion 8204. In addition, the main body 8203 includes a camera, and information on the movement of a user's eyeball or eyelid can be used as an input means.

In addition, the wearing portion 8201 may be provided with a plurality of electrodes capable of sensing current flowing in response to the movement of the user's eyeball in a position in contact with the user to have a function of recognizing a user's line of sight. Furthermore, the wearing portion 8201 may have a function of monitoring a user's pulse with the use of current flowing through the electrodes. Moreover, the wearing portion 8201 may include a variety of sensors such as a temperature sensor, a pressure sensor, and an acceleration sensor to have a function of displaying user's biological information on the display portion 8204, a function of changing video displayed on the display portion 8204 in accordance with the movement of the user's head, or the like.

The display device according to one embodiment of the present invention can be employed for the display portion 8204.

FIG. 29C to FIG. 29E are diagrams illustrating the appearance of a head-mounted display 8300. The head-mounted display 8300 includes a housing 8301, a display portion 8302, band-like fixing units 8304, and a pair of lenses 8305.

The user can see display on the display portion 8302 through the lenses 8305. Note that the display portion 8302 is preferably placed and curved because the user can feel high realistic sensation. In addition, when another image displayed on a different region of the display portion 8302 is seen through the lenses 8305, three-dimensional display using parallax or the like can also be performed. Note that the structure is not limited to the structure in which one display portion 8302 is provided; two display portions 8302 may be provided and one display portion may be provided per user's eye.

The display device according to one embodiment of the present invention can be employed for the display portion 8302. The display device according to one embodiment of the present invention can also achieve extremely high definition. For example, a pixel is not easily seen by the user even when the user sees display that is magnified by the use of the lenses 8305 as illustrated in FIG. 29E. In other words, video with a strong sense of reality can be seen by the user with the use of the display portion 8302.

FIG. 29F is a diagram illustrating the appearance of a goggle-type head-mounted display 8400. The head-mounted display 8400 includes a pair of housings 8401, a wearing portion 8402, and a shock-absorbing member 8403. A display portion 8404 and a lens 8405 are provided in each of the pair of housings 8401. When the pair of display portions 8404 display different images, three-dimensional display using parallax can be performed.

The user can see the display portion 8404 through the lens 8405. The lens 8405 has a focus adjustment mechanism, and the focus adjustment mechanism can adjust the position of the lens 8405 according to user's eyesight. The display portion 8404 is preferably a square or a horizontal rectangle. This can increase realistic sensation.

The wearing portion 8402 preferably has plasticity and elasticity to be adjusted to fit the size of a user's face and not to slide down. In addition, part of the wearing portion 8402 preferably has a vibration mechanism to function as a bone conduction earphone. Thus, without additionally requiring an audio device such as earphones or a speaker, the user can enjoy video and sound only by wearing the head-mounted display 8400. Note that the housing 8401 may have a function of outputting audio data through wireless communication.

The wearing portion 8402 and the shock-absorbing member 8403 are portions in contact with the user's face (forehead, cheek, or the like). The shock-absorbing member 8403 is in close contact with the user's face, so that light leakage can be prevented, which further increases the sense of immersion. A soft material is preferably used for the shock-absorbing member 8403 so that the shock-absorbing member 8403 is in close contact with the face of the user wearing the head-mounted display 8400. For example, a material such as rubber, silicone rubber, urethane, or a sponge can be used. Furthermore, when a sponge or the like whose surface is covered with cloth, leather (natural leather or synthetic leather), or the like is used, a gap is less likely to be generated between the user's face and the shock-absorbing member 8403, so that light leakage can be suitably prevented. Furthermore, using such a material is preferable because it has a soft texture and the user does not feel cold when wearing the head-mounted display 8400 in a cold season, for example. The member in contact with user's skin, such as shock-absorbing member 8403 or the wearing portion 8402, is preferably detachable because cleaning or replacement can be easily performed.

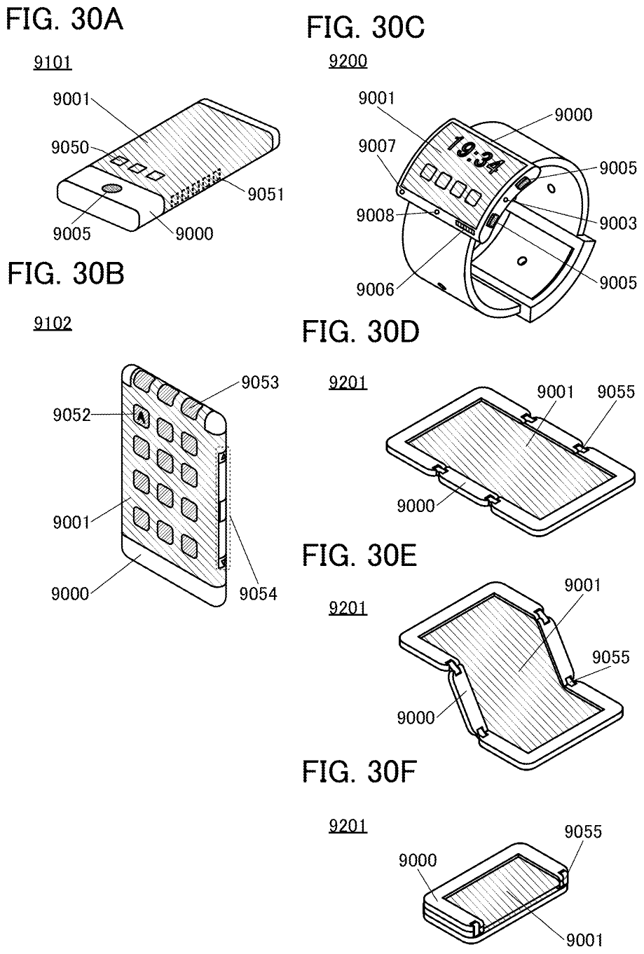

Electronic devices illustrated in FIG. 30A to FIG. 30F include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 30A to FIG. 30F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a storage medium. Note that the functions of the electronic devices are not limited thereto, and the electronic devices can have a variety of functions. The electronic devices may include a plurality of display portions. In addition, the electronic devices may each be provided with a camera or the like and have a function of taking a still image or a moving image and storing the taken image in a storage medium (an external storage medium or a storage medium incorporated in the camera), a function of displaying the taken image on the display portion, or the like.

The display device according to one embodiment of the present invention can be employed for the display portion 9001.

The electronic devices illustrated in FIG. 30A to FIG. 30F are described in detail below.

FIG. 30A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 30A illustrates an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; the reception strength of an antenna; and the like. Alternatively, the icon 9050 or the like may be displayed at the position where the information 9051 is displayed.

FIG. 30B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 in a position that can be observed from above the portable information terminal 9102, with the portable information terminal 9102 put in a breast pocket of his/her clothes. The user can see display without taking out the portable information terminal 9102 from the pocket and determine whether to answer a call, for example.

FIG. 30C is a perspective view illustrating a wristwatch-type portable information terminal 9200. For example, the portable information terminal 9200 can be used as a Smartwatch (registered trademark). In addition, the display surface of the display portion 9001 is provided and curved, and display can be performed along the curved display surface. Furthermore, mutual communication between the portable information terminal 9200 and, for example, a headset capable of wireless communication enables hands-free calling. Moreover, with the connection terminal 9006, the portable information terminal 9200 can perform mutual data transmission with another information terminal and charging. Note that a charging operation may be performed by wireless power feeding.

FIG. 30D to FIG. 30F are perspective views illustrating a foldable portable information terminal 9201. In addition, FIG. 30D is a perspective view of an opened state of the portable information terminal 9201, FIG. 30F is a perspective view of a folded state thereof, and FIG. 30E is a perspective view of a state in the middle of change from one of FIG. 30D and FIG. 30F to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of structure examples, drawings corresponding thereto, and the like described in this embodiment can be combined with the other structure examples, the other drawings corresponding thereto, and the like as appropriate.

### REFERENCE NUMERALS

C1: semiconductor layer, Cia: semiconductor layer, C1b: semiconductor layer, C1c: semiconductor layer, Cid: semiconductor layer, d1: distance, d2: distance, GL1: wiring, GL2: wiring, GL3: wiring, Px: pixel, Px1: pixel, Px1a: pixel, Pxb: pixel, Pxc: pixel, Px2: pixel, Px2a: pixel, Px2b: pixel, Px2c: pixel, Px3: pixel, Px3a: pixel, Px3b: pixel, Px3c: pixel, V0: wiring, V0a: wiring, V0b: wiring, V0c: wiring, V0d: wiring, 1B: subpixel, 1G: subpixel, 1R: subpixel, 2B: subpixel, 2G: subpixel, 2R: subpixel, 11: pixel, 11_1: pixel, 11_2: pixel, 11f: pixel, 11g: pixel, 12: wiring, 12a: wiring, 12b: wiring, 12c: wiring, 12d: wiring, 20: layer, 20b1: transistor, 23: display portion driver circuit, 23a: circuit portion, 23b: circuit portion, 29: terminal portion, 29a: FPC, 30: layer, 31: display portion, 31a: region, 40: sealing substrate, 51: pixel circuit, 52A: transistor, 52B: transistor, 52C: transistor, 52D: transistor, 52E: transistor, 52F: transistor, 53: capacitor, 53A: capacitor, 53B: capacitor, 55: protection circuit, 56: semiconductor element, 60: layer, 61: light-emitting element, 100A: semiconductor device, 111: pixel electrode, 111B: pixel electrode, 111G: pixel electrode, 111R: pixel electrode, 112: EL layer, 112B: EL layer, 112G: EL layer, 112R: EL layer, 113: common electrode, 114: common layer, 131: insulating layer, 131a: insulating layer, 131b: insulating layer, 132: insulating layer, 230: pixel matrix, 232: first driver circuit, 232a: first driver circuit, 232b: first driver circuit, 233: second driver circuit, 236: wiring, 237: wiring, 240: capacitor, 240b: capacitor, 240c: capacitor, 241: conductive layer, 243: insulating layer, 245: conductive layer, 251: conductive layer, 252: conductive layer, 254: insulating layer, 255: insulating layer, 256: plug, 256a: plug, 256b: plug, 258: insulating layer, 259: insulating layer, 260: insulating layer, 261: insulating layer, 262: insulating layer, 263: insulating layer, 264: insulating layer, 265: insulating layer, 266: insulating layer, 267: insulating layer, 268: insulating layer, 269: insulating layer, 270: insulating layer, 271a: conductive layer, 271c: conductive layer, 274: plug, 274a: conductive layer, 274b: conductive layer, 275: plug, 275a: conductive layer, 275b: conductive layer, 301: substrate, 310: transistor, 320: transistor, 320a: transistor, 320b1: transistor, 320b2: transistor, 320c: transistor, 321: semiconductor layer, 323: insulating layer, 324: conductive layer, 325: conductive layer, 325a: conductive layer, 325b: conductive layer, 326: insulating layer, 327: conductive layer, 328: insulating layer, 329: insulating layer, 331: substrate, 332: insulating layer, 400A: display device, 400B: display device, 400C: display device, 416: protective layer, 419: resin layer, 420: substrate, 430: light-emitting element, 430a: light-emitting element, 430b: light-emitting element, 430b1: light-emitting element, 430b2: light-emitting element, 430c: light-emitting element, 772: lower electrode, 785: coloring layer, 786: EL layer, 786a: EL layer, 786b: EL layer, 788: upper electrode, 4411: light-emitting layer, 4412: light-emitting layer, 4413: light-emitting layer, 4420: layer, 4420-1: layer, 4420-2: layer, 4430: layer, 4430-1: layer, 4430-2: layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal device, 7400: digital signage, 7401: pillar, 7411: information terminal device, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: wearing portion, 8202: lens, 8203: main body, 8204: display portion, 8205: cable, 8206: battery, 8300: head-mounted display, 8301: housing, 8302: display portion, 8304: fixing unit, 8305: lens, 8400: head-mounted display, 8401: housing, 8402: wearing portion, 8403: shock-absorbing member, 8404: display portion, 8405: lens, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, and 9201: portable information terminal.

1. A display device comprising:
a display portion;
a first wiring;
a second wiring;
a third wiring; and
a fourth wiring,
wherein the display portion includes a first pixel, a second pixel, and a third pixel,
wherein the second pixel is positioned between the first pixel and the third pixel in a plan view,
wherein the first pixel, the second pixel, and the third pixel each include a first subpixel and a second subpixel,
wherein the first wiring is configured to apply a first potential to the second subpixel included in the first pixel,
wherein the second wiring is configured to apply the first potential to the first subpixel included in the second pixel,
wherein the third wiring is configured to apply the first potential to the second subpixel included in the second pixel,
wherein the fourth wiring is configured to apply the first potential to the first subpixel included in the third pixel,
wherein the first wiring and the second wiring are adjacent to each other,
wherein the third wiring and the fourth wiring are adjacent to each other, and
wherein a distance between the first wiring and the second wiring is shorter than a distance between the third wiring and the fourth wiring.

2. The display device according to claim 1,
wherein the first subpixel is configured to control light corresponding to a first color selected from red, green, and blue, and
wherein the second subpixel is configured to control light corresponding to a second color different from the first color among red, green, and blue.

3. The display device according to claim 1, further comprising:
a fifth wiring;
a sixth wiring;
a seventh wiring; and
an eighth wiring,
wherein the fifth wiring is configured to supply a first signal to the second subpixel included in the first pixel,
wherein the sixth wiring is configured to supply a second signal to the first subpixel included in the second pixel,
wherein the seventh wiring is configured to supply a third signal to the second subpixel included in the second pixel,
wherein the eighth wiring is configured to supply a fourth signal to the first subpixel included in the third pixel,
wherein the first wiring and the second wiring are positioned between the fifth wiring and the sixth wiring in a plan view, and
wherein the third wiring and the fourth wiring are positioned between the seventh wiring and the eighth wiring in a plan view.

4. The display device according to claim 1, further comprising:
a display portion driver circuit;
a ninth wiring electrically connected to the display portion driver circuit; and
a tenth wiring electrically connected to the display portion driver circuit,
wherein the ninth wiring and the tenth wiring are each configured to serve as a scan line,
wherein the ninth wiring includes a first region overlapped with the first pixel, and
wherein the tenth wiring includes a second region overlapped with the second pixel and a third region overlapped with the third pixel.

5. The display device according to claim 1,
wherein the second subpixel included in the first pixel includes a first transistor,
wherein the first subpixel included in the second pixel includes a second transistor, and the second subpixel included in the second pixel includes a third transistor,
wherein the first subpixel included in the third pixel includes a fourth transistor,
wherein one of a source and a drain of the first transistor is electrically connected to the first wiring,
wherein one of a source and a drain of the second transistor is electrically connected to the second wiring,
wherein one of a source and a drain of the third transistor is electrically connected to the third wiring,
wherein one of a source and a drain of the fourth transistor is electrically connected to the fourth wiring,
wherein the first wiring and the second wiring are placed between a channel formation region of the first transistor and a channel formation region of the second transistor in a plan view, and
wherein the third wiring and the fourth wiring are placed between a channel formation region of the third transistor and a channel formation region of the fourth transistor in a plan view.

6. The display device according to claim 5,
wherein the display portion includes a first light-emitting element, a second light-emitting element, a third light-emitting element, and a fourth light-emitting element,
wherein the other of the source and the drain of the first transistor is electrically connected to the first light-emitting element,
wherein the other of the source and the drain of the second transistor is electrically connected to the second light-emitting element,
wherein the other of the source and the drain of the third transistor is electrically connected to the third light-emitting element, and
wherein the other of the source and the drain of the fourth transistor is electrically connected to the fourth light-emitting element.

7. The display device according to claim 5, further comprising:
a display portion driver circuit;
a ninth wiring electrically connected to the display portion driver circuit; and
a tenth wiring electrically connected to the display portion driver circuit,
wherein the ninth wiring and the tenth wiring are each configured to serve as a scan line,
wherein the ninth wiring is electrically connected to a gate of the first transistor,
wherein the tenth wiring is electrically connected to a gate of the second transistor, a gate of the third transistor, and a gate of the fourth transistor,
wherein the ninth wiring includes a first region overlapped with the first pixel, and
wherein the tenth wiring includes a second region overlapped with the second pixel and a third region overlapped with the third pixel.

8. The display device according to claim 4,
wherein the ninth wiring is overlapped with neither the second pixel nor the third pixel,
wherein the tenth wiring is not overlapped with the first pixel, and
wherein the ninth wiring and the tenth wiring are not in contact with each other in the display portion.

9. A display device comprising:
a first pixel;
a second pixel;
a third pixel;
a first wiring;
a second wiring; and
a third wiring,
wherein the second pixel is positioned between the first pixel and the third pixel in a plan view,
wherein the first pixel, the second pixel, and the third pixel each include a first subpixel and a second subpixel,
wherein the first subpixel is configured to control light corresponding to a first color selected from red, green, and blue,
wherein the second subpixel is configured to control light corresponding to a second color different from the first color among red, green, and blue,
wherein the first wiring is configured to apply a first potential to the second subpixel included in the first pixel and the first subpixel included in the second pixel,
wherein the second wiring is configured to apply the first potential to the second subpixel included in the second pixel,
wherein the third wiring is configured to apply the first potential to the first subpixel included in the third pixel,
wherein the second wiring and the third wiring are adjacent to each other, and
wherein the first wiring has a larger width than each of the second wiring and the third wiring.

10. The display device according to claim 9, further comprising:
a fourth wiring;
a fifth wiring;
a sixth wiring; and
a seventh wiring,
wherein the fourth wiring is configured to supply a signal to the second subpixel included in the first pixel,
wherein the fifth wiring is configured to supply a signal to the first subpixel included in the second pixel,
wherein the sixth wiring is configured to supply a signal to the second subpixel included in the second pixel,
wherein the seventh wiring is configured to supply a signal to the first subpixel included in the third pixel,
wherein the first wiring is placed between the fourth wiring and the fifth wiring in a plan view, and
wherein the second wiring and the third wiring are placed between the sixth wiring and the seventh wiring in a plan view.

11. The display device according to claim 9,
wherein the second subpixel included in the first pixel includes a first transistor,
wherein the first subpixel included in the second pixel includes a second transistor, and the second subpixel included in the second pixel includes a third transistor,
wherein the third pixel includes a fourth transistor,
wherein one of a source and a drain of the first transistor and one of a source and a drain of the second transistor are electrically connected to the first wiring,
wherein one of a source and a drain of the third transistor is electrically connected to the second wiring,
wherein one of a source and a drain of the fourth transistor is electrically connected to the third wiring,
wherein the first wiring is placed between a channel formation region of the first transistor and a channel formation region of the second transistor, and
wherein the second wiring and the third wiring are placed between a channel formation region of the third transistor and a channel formation region of the fourth transistor.

12. An electronic device comprising:
the display device according to claim 1;
an antenna; and
a sensor.

13. A method for manufacturing a display device comprising a display portion over a first substrate, comprising the steps of:
forming n transistors, n being an integer greater than or equal to 2, arranged in a matrix in a region to be the display portion over the first substrate;
depositing a first conductive film over the n transistors;
depositing a photo resist over the first conductive film;
transferring a desired pattern through light exposure treatment on the photo resist onto the region to be the display portion;
forming the desired pattern on the photo resist through development treatment on the photo resist;
forming n wirings by removing part of the first conductive film with the use of the desired pattern; and
forming n light-emitting elements arranged in a matrix over the n transistors,
wherein the n wirings are electrically connected to the n transistors one by one,
wherein the step of transferring includes a step of performing light exposure on a plurality of divided light exposure regions over the region to be the display portion,
wherein among the n wirings, a first wiring is formed through light exposure in a first light exposure region, and a second wiring is formed through light exposure in a second light exposure region,
wherein the first wiring and the second wiring are adjacent to each other,
wherein among the n transistors, a first transistor is electrically connected to the first wiring, and a second transistor is electrically connected to the second wiring, and
wherein the first wiring and the second wiring are placed between a channel formation region of the first transistor and a channel formation region of the second transistor in a plan view.

14. The method for manufacturing a display device according to claim 13,
wherein the n wirings are electrically connected to ones of sources and drains of the n transistors one by one, and
wherein the others of the sources and the drains of the n transistors are electrically connected to the n light-emitting elements one by one and are overlapped with each other one by one.

15. The method for manufacturing a display device according to claim 13, wherein the n light-emitting elements each include an EL layer.

16. The method for manufacturing a display device according to claim 13, wherein light exposure treatment is performed so that in a connection portion of adjacent light exposure regions in the plurality of light exposure regions, a light exposure region where parts of the adjacent light exposure regions are overlapped with each other is formed.
